(19) United States
(12) Patent Application Publication
(10) Pub. No.: US 2008/0130918 A1
(43) Pub. Date: Jun. 5, 2008

(54) Apparatus, method and program for processing audio signal

(75) Inventor: Tadaaki Kimijima, Tokyo (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 11/890,369

(22) Filed: Aug. 6, 2007

(30) Foreign Application Priority Data
Aug. 9, 2006 (JP) JP2006-216820

(51) Int. Cl. H03G 3/00

(52) U.S. Cl. 381/107

(57) ABSTRACT

An apparatus for processing an audio signal includes a separator for separating an input audio signal into a first audio signal designated by a user and a second audio signal not containing the first audio signal, a measurement unit for measuring an audio volume balance between the first audio signal and the second audio signal, and an adjuster for calculating an adjustment value to the audio volume of the first audio signal and an adjustment value to the audio volume of the second audio signal based on an audio volume balance designated by the user, and adjusting the audio volume balance between the first and second audio signals.

### CROSS REFERENCES TO RELATED APPLICATIONS

The present invention contains subject matter related to Japanese Patent Application JP 2006-216820 filed in the Japanese Patent Office on Aug. 9, 2006, the entire contents of which are incorporated herein by reference.

### BACKGROUND OF THE INVENTION

1. Field of the Invention

The present invention relates to an apparatus, method, and program for processing an audio signal from a sound source localized in an angle or an audio signal from a sound source of a target type.

2. Description of the Related Art

Sounds from a variety of types of sound sources are contained in content recorded on a compact disk (CD) or a digital versatile disk (DVD) and broadcast television (TV) content. For example, recorded music content may contain sounds from sound sources from singing voice or a musical instrument. TV broadcast content may contain a voice of a performer, effect sounds, laughter or clapping sounds.

These sounds may be picked up by separate microphones during recording. But audio signals may be sorted to a predetermined number of channels such as 2 channels (2 ch) or 5.1 channels (5.1 ch). A mixing operation is performed so that these sounds are localized at angles corresponding to the respective sound sources. The word “channel” is sometimes hereinafter referred to as “ch.”

Techniques for separating an audio signal, namely, a mixture of a plurality of sounds from a plurality of sound sources, into audio signals of the plurality of sound sources are disclosed in Japanese Unexamined Patent Application Publication Nos. 2006-121152, 2006-080708, and 2006-014220.

### SUMMARY OF THE INVENTION

When content containing an audio signal, a mixture of sounds from a plurality of sound sources, is reproduced (received and demodulated) on a reproducing apparatus or a TV receiver, each of the audio signals of the plurality of sound sources is reproduced at a location angle adjusted at the recording.

However, some users may not be comfortable with a localization of a sound source intended by a producer side. Some users may wish to enjoy content more. For example, one user may wish to extract a sound of a sound source within a frequency range localized at an angle, and another user may wish to modify the audio volume of the sound source within the frequency range localized at the angle.

The inventors of this invention have proposed in Japanese Patent Application No. 2005-327237 (Serial No. 0590529003) a technique that allows a sound source to be adjusted on a per location angle basis. In accordance with the disclosed technique, an audio signal of a sound source localized at an angle is extracted or erased. The audio volume of the sound is adjusted on a per location angle basis.

In accordance with the disclosed technique, a user himself adjusts the sound while listening to the sound. The technique can reflect the user's own preference in sound. However, the audio volume of the audio signal of each sound source is different from content to content and from scene to scene. The type of the sound source localized at a certain angle is also different from content to content and from scene to scene. When different pieces of content are reproduced, the user himself needs to adjust, and the adjustment operation can be time-consuming.

It is thus desirable to adjust automatically an audio volume balance between an audio signal from a target sound source and an audio signal from a sound source other than the target sound source to the user's preference without frequent user's intervention.

In accordance with one embodiment of the present invention, an apparatus for processing an audio signal, includes a separator for separating an input audio signal into a first audio signal designated by a user and a second audio signal not containing the first audio signal, a measurement unit for measuring an audio volume balance between the first audio signal and the second audio signal, and an adjuster for calculating an adjustment value to the audio volume of the first audio signal and an adjustment value to the audio volume of the second audio signal based on an audio volume balance designated by the user, and adjusting the audio volume balance between the first and second audio signals.

The separator separates the input audio signal to be processed into the audio signal of the designated sound source (first audio signal) and the audio signal of the other sound source (second audio signal). For example, the audio signal to be processed is separated into an audio signal of a human voice (first audio signal) and an audio signal other than human voice (second audio signal). The measurement unit measures the audio volume balance between the first audio signal and the second audio signal.

The adjuster calculates an adjustment value to the audio volume of the first audio signal and an adjustment value to the audio volume of the second audio signal based on an audio volume balance designated by the user, and then adjusts the audio volume balance between the first and second audio signals.

The audio volume balance is thus adjusted so that the first audio signal as the audio signal of the target sound source is pronounced while the other audio signals is not. This adjustment is automatically performed to the user's preference without the need for the user's frequent intervention.

In accordance with another embodiment of the present invention, the separator may separate, as the first audio signal, an audio signal localized within a separation angle designated by the user and, as the second audio signal, an audio signal of a sound source localized outside the separation angle.

The separator separates, as the first audio signal, the audio signal localized within the separation angle designated by the user (an audio signal within a separation angle range) and, as the second audio signal, the audio signal of the sound source localized outside the separation angle (an audio signal outside the separation angle range). The first audio signal as the audio signal of the target sound source is thus pronounced while the other audio signals are not.

In accordance with another embodiment of the present invention, the separator may separate, as the first audio signal, an audio signal of a sound source of a type designated by the user and, as the second audio signal, an audio signal of a sound source not containing the sound source type designated by the user.

The separator thus separates, as the first audio signal, the audio signal of the sound source of the type designated by the user and, as the second audio signal, the audio signal of the sound source not containing the sound source type designated by the user. The first audio signal as the audio signal of the target sound source is thus pronounced while the other audio signals are not.

In accordance with embodiments of the present invention, the audio volume balance between the audio signal of a target sound source and the audio signal of the sound sources other than the target sound source contained in the same audio signal is automatically adjusted to an appropriate state.

### BRIEF DESCRIPTION OF THE DRAWINGS

FIG. 1 is a block diagram of a reproducing apparatus in accordance with a first embodiment of the present invention;

FIG. 2 is an external view of a remote commander;

FIG. 3 is a block diagram of a first configuration of an audio signal processor in the reproducing apparatus of FIG. 1;

FIG. 4 is a flowchart illustrating a process of the reproducing apparatus incorporating the audio signal processor of FIG. 3 in accordance with the first embodiment of the present invention;

FIG. 5 is a block diagram illustrating a second configuration of the audio signal processor in the reproducing apparatus of FIG. 1;

FIG. 6 is a block diagram illustrating the structure of a location angle and level calculator;

FIG. 7 is a flowchart illustrating a process of the reproducing apparatus incorporating the audio signal processor discussed with reference to FIGS. 5 and 6 in accordance with the first embodiment of the present invention;

FIG. 8 is a continuation of the flowchart of FIG. 7;

FIG. 9 is a block diagram illustrating the structure of a reproducing apparatus in accordance with a second embodiment of the present invention;

FIG. 10 is a block diagram illustrating an audio signal processor in the reproducing apparatus of FIG. 9;

FIG. 11 is a flowchart illustrating a process of the reproducing apparatus of the second embodiment of the present invention incorporating the audio signal processor of FIG. 10;

FIG. 12 is a block diagram illustrating a recording and reproducing apparatus in accordance with a third embodiment of the present invention;

FIG. 13 is a block diagram illustrating a recording and reproducing apparatus in accordance with a fourth embodiment of the present invention;

FIG. 14 is a block diagram illustrating the reproducing apparatus incorporating a first user interface;

FIG. 15 illustrates a display example of information relating to source sounds to be reproduced and displayed on a display screen of a display;

FIG. 16 illustrates a display example displayed on the display screen for designating a separation angle;

FIG. 17 illustrates a display example displayed on the display screen for designating a separation angle;

FIG. 18 is a flowchart illustrating a reception process for receiving command inputs relating to a separation angle and audio volume balance;

FIG. 19 is a continuation of the flowchart of FIG. 18;

FIG. 20 illustrates a display example displayed on the display screen of the display on which a touchpanel is glued;

FIG. 21 illustrates the structure of an audio signal processor incorporating a second user interface;

FIG. 22 illustrates a display example displayed on the display screen to designate a separation angle range and a frequency range;

FIG. 23 illustrates a display example displayed on the display screen to designate the separation angle range and the frequency range;

FIG. 24 illustrates a setting example in which the separation angle range (including the frequency range and location angle range) is set; and

FIG. 25 illustrates another setting example in which the separation angle range (including the frequency range and location angle range) is set.

### DESCRIPTION OF THE PREFERRED EMBODIMENTS

An apparatus, method and computer program for processing an audio signal are described below with reference to the drawings.

### First Embodiment

The apparatus, method, and computer program for processing the audio signal in accordance with a first embodiment of the present invention are described below. The apparatus herein is a reproducing apparatus.

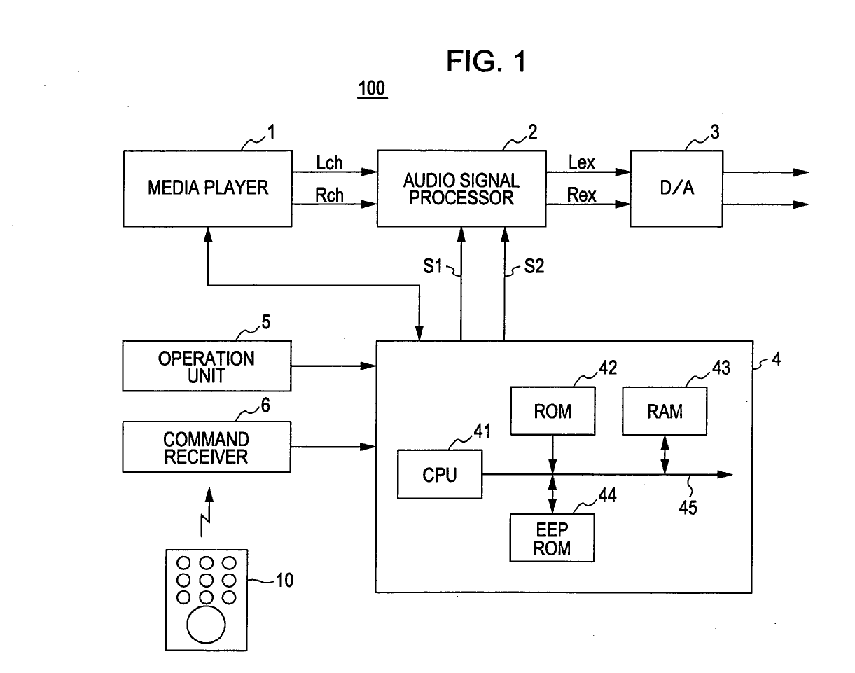

FIG. 1 is a block diagram illustrating a reproducing apparatus 100 of the first embodiment of the present invention. The reproducing apparatus 100 of FIG. 1 includes a media player 1, an audio signal processor 2, a digital-to-analog (D/A) converter 3, a system controller 4, an operation unit 5 and a command receiver 6. The reproducing apparatus 100 can be remote controlled by a remote commander 10.

The media player 1 reads and reproduces an audio signal recorded on a predetermined recording medium. The recording medium is one of an optical recording disk (such as a compact disk (CD), a digital versatile disk (DVD), or a blu-ray disk), a magneto-optical disk (such as Mini Disk (MD (Registered Trademark))), a magnetic disk (such as a hard disk), and a semiconductor memory.

The recording medium supported by the media player 1 records content of two audio signal channels, namely, Lch (left channel) and Rch (right channel). These audio signals Lch and Rch reproduced by the media player 1 are fed to the audio signal processor 2.

The audio signal processor 2 performs a predetermined audio signal process on each of an audio signal of a sound source localized in a designated angle range and an audio signal of a sound range localized outside the designated angle range, in accordance with the audio signals Lch and Rch from the media player 1 and a separation angle command signal S1 and an audio volume balance command signal S2 from the system controller 4 to be discussed later. The internal structure of the audio signal processor 2 will be specifically described later. The audio signals Lch and Rch having undergone the predetermined audio signal process through the audio signal processor 2 are fed to the digital-to-analog converter 3.

The digital-to-analog converter 3 digital-to-analog converts one digital signal from the audio signal processor 2 as an audio signal Lex into an analog audio signal L of Lch and the other digital signal from the audio signal processor 2 as an audio signal Rex into an analog audio signal R. The analog audio signal L of Lch and the analog audio signal R of Rch are thus output. The audio signals of Lch and Rch having undergone the predetermined signal process in the audio signal processor 2 are supplied to loudspeakers, and the corresponding sounds are output from the loudspeakers.

As shown in FIG. 1, the system controller 4 is a microcomputer including a central processing unit (CPU) 41, a read-only memory (ROM) 42, a random-access memory (RAM) 43, a non-volatile memory such as an electrically erasable and programmable ROM (EEPROM) 44, and a CPU bus 45 that interconnects all these elements. The system controller 4 generally controls the reproducing apparatus 100 of the first embodiment.

As shown in FIG. 1, the system controller 4 connects to the operation unit 5 and the command receiver 6. The operation unit 5 includes a variety of controls exposed outside the casing of the reproducing apparatus 100. The operation unit 5 receives a variety of operation inputs on the controls from a user, generates command signals responsive to the received operation inputs, and then supplies the command signals to the system controller 4.

The command receiver 6 receives the command signals, for example, conveyed in the form of infrared signals transmitted from the remote commander 10, converts the received command signals into respective electrical signals, and supplies the electrical command signals to the system controller 4. The remote commander 10 also includes a variety of controls. The command receiver 6 receives and converts a command signal in the form of infrared signal generated in response to the operation of each control on the remote commander 10 into an electrical signal, and supplies the electrical signal to the system controller 4.

In response to the command signal from one of the operation unit 5 and the command receiver 6, the system controller 4 generally controls the reproducing apparatus 100 of the first embodiment of the present invention. The reproducing apparatus 100 thus operates in response to the operation input from the user. For example, each of the operation unit 5 and the remote commander 10 includes a control for issuing a play command for reproducing content stored on a recording medium loaded on the media player 1. Upon receiving the command signal responsive to the operation on the control, the system controller 4 controls the media player 1 to start a content playing process.

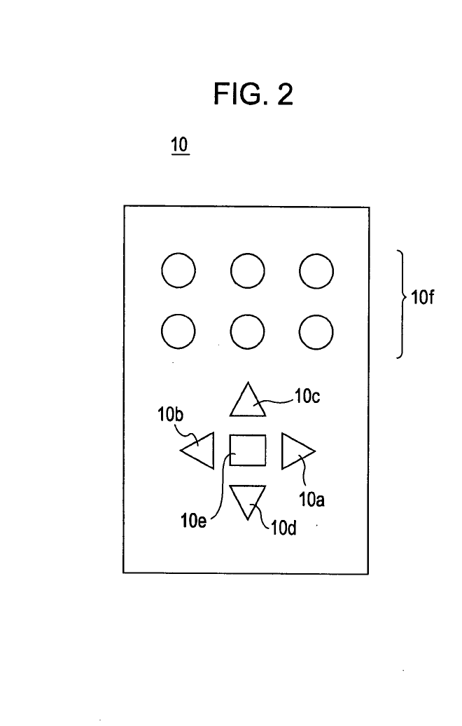

FIG. 2 is an external view of the remote commander 10 for the reproducing apparatus 100 of the first embodiment of the present invention. As shown in FIG. 2, the remote commander 10 is provided with direction command keys including a right key 10a, a left key 10b, an up key 10c, and a down key 10d, and an entry key 10e.

A user operates one of the right key 10a and the left key 10b on the reproducing apparatus 100 of the first embodiment, thereby issuing a command specifying a separation location angle (command input). By operating one of the up key 10c and the down key 10d, the user can issue to the reproducing apparatus 100 an audio volume balance command (command input) to balance audio volume of an audio signal of a sound source localized within the specified angle and an audio signal of a sound source localized outside the specified angle.

The system controller 4 generates the separation angle command signal S1 to be supplied to the audio signal processor 2, in response to the command input responsive to the user operation on the right key 10a and the left key 10b on the remote commander 10 of FIG. 2. More specifically, the separation angle command signal S1 is information indicating a separation location angle generated in response to the user operation input (separation angle command information) received via the right key 10a and the left key 10b.

The system controller 4 generates the audio volume balance command signal S2 to be supplied to the audio signal processor 2, in response to the command signal input responsive to the user operation on the up key 10c and the down key 10d on the remote commander 10 of FIG. 2. More specifically, the audio volume balance command signal S2 is information indicating audio volume balance generated in response to a command input from the user on the up key 10c and the down key 10d (audio volume balance command information).

In the reproducing apparatus 100 of the first embodiment, the system controller 4 generates and supplies the separation angle command signal S1 and the audio volume balance command signal S2 to the audio signal processor 2 prior to reproducing the audio signal recorded on the recording medium loaded on the media player 1. For example, as described above, the system controller 4 receives the separation angle command information and the audio volume balance command information input from the user on the remote commander 10.

In response to the separation angle and audio volume balance commands from the user, the reproducing apparatus 100 determines the audio volume balance between the audio signal of the sound source localized within the designated angle (within separation angle range) and the audio signal of the sound source localized outside the designated angle (outside the separation angle range). The reproducing apparatus 100 automatically adjusts the audio volume balance and reproduces the audio signal at an optimum audio volume balance without the user's intervention.

The separation angle command information and the audio volume balance command information can be input each time a target audio signal is reproduced. Alternatively, the separation angle command information and the audio volume balance command information may be input beforehand to the reproducing apparatus 100 and recorded on the EEPROM 44 in the system controller 4.

Once the separation angle command information and the audio volume balance command information are input, no further entry of these pieces of information is required. Using the separation angle command information and the audio volume balance command information stored on the EEPROM 44, the separation angle command signal S1 and the audio volume balance command signal S2 are generated, and used. The audio signal is reproduced with the audio volume balance appropriately adjusted without the user's intervention.

It is also possible to store identification information of a set of music data to be reproduced, such as a song, and the separation angle command information and the audio volume balance command information in association with each other on the EEPROM 44. In this way, the audio volume balance is appropriately adjusted on a per audio signal basis using appropriate separation angle command information and audio volume balance command information so that the user can listen to the audio signal at an optimum audio volume balance.

A plurality of pieces of separation angle command information and audio volume balance command information may be stored. Prior to the playing of the audio signal, a command input indicating which separation angle command information to use and which audio volume balance command information to use is received in response to an audio signal to be reproduced. Using the specified separation angle command information and audio volume balance command information, the separation angle command signal S1 and the audio volume balance command signal S2 are generated.

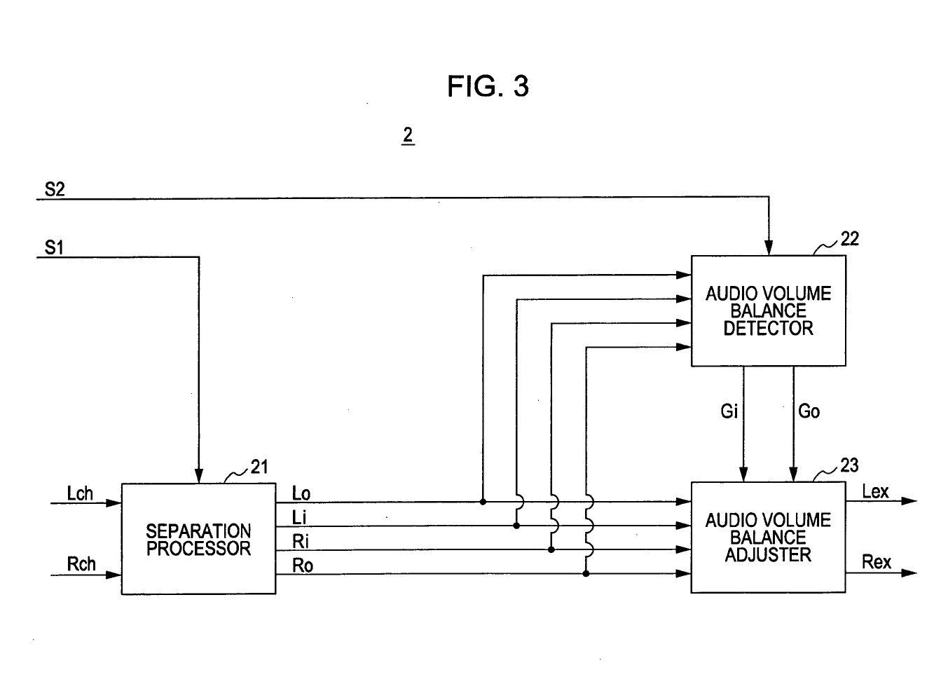

FIG. 3 is a block diagram illustrating a first configuration of the audio signal processor 2 in the reproducing apparatus 100 of the first embodiment. The audio signal processor 2 first separates a target audio signal into an audio signal of a sound source localized in a designated angle and an audio signal of a sound source localized outside the designated angle. The audio volume balance is measured, and then adjusted in response to a designated audio volume balance.

As shown in FIG. 3, the audio signal processor 2 includes a separation processor 21, an audio volume balance detector 22 and an audio volume balance adjuster 23. As shown in FIG. 3, the separation processor 21 receives left and right audio signals Lch and Rch and the separation angle command signal S1 supplied from the system controller 4 as previously discussed with reference to FIG. 1.

In response to the separation angle command signal S1 from the system controller 4, the separation processor 21 separates each of the supplied audio signals Lch and Rch into audio signals Li and Ri (suffix “i” represents inner) of the sound source within the designated angle (within the separation angle range) and audio signals Lo and Ro (suffix “o” represents outer) of the sound source outside the designated angle. Each of these four signals is output to each of the audio volume balance detector 22 and the audio volume balance adjuster 23.

The separation processor 21 may have any circuit structure as long as the circuit can separate the input audio signal in response to the separation angle command signal S1 into the audio signal of the sound source localized within the designated angle and the audio signal of the sound source localized outside the designated angle. For example, the separation processor 21 may include a circuit disclosed in Japanese Patent Application No. 2005-327237 (Serial No. 0590529003).

As shown in FIG. 3, the audio volume balance detector 22 receives the audio signal Li within the location angle (within the separation angle) of Lch, the audio signal Ri within the location angle (within the separation angle) of Rch, the audio signal Lo outside the location angle (outside the separation angle) of Lch, and the audio signal Ro outside the location angle (outside the separation angle) of Rch, separated by the separation processor 21. The audio volume balance detector 22 thus measures the audio volume balance between the designated inner angle and the designated outer angle. In response to the audio volume balance command signal S2 from the system controller 4, the audio volume balance detector 22 determines a gain value Gi to the audio signal within the separation angle and a gain value Go to the audio signal outside the separation angle so that the audio volume balance between the audio signal within the separation angle and the audio signal outside the separation angle becomes appropriate. The audio volume balance detector 22 then supplies the determined gain values Gi and Go to the audio volume balance adjuster 23.

As shown in FIG. 3, the audio volume balance adjuster 23 receives the audio signal Li of Lch within the separation angle, the audio signal Ri of Rch within the separation angle, the audio signal Lo of Lch outside the separation angle and the audio signal Ro of Rch outside the separation angle, separated by the separation processor 21, and the gain value Gi to the audio signal within the separation angle and the gain value Go to the audio signal outside the separation angle supplied from the audio volume balance detector 22. The audio volume balance adjuster 23 then performs a calculation operation of equation (1), thereby generating and outputting an output audio signal Lex of Lch and an output audio signal Rex of Rch.

Lex=Li×Gi+Lo×Go

Rex=Ri×Gi+Ro×Go (1)

Several methods of measuring an audio volume balance the audio volume balance detector 22 can adopt are contemplated.

For example, a sum signal of the audio signal Li of Lch within the separation angle and the audio signal Ri of Rch within the separation angle (Li+Ri=sum_inner) and a sum signal of the audio signal Lo of Lch outside the separation angle and the audio signal Ro of Rch outside the separation angle (Lo+Ro=sum_outer) may be respectively monitored for 5 seconds, and a peak value (peak_inner) of the sum signal (sum_inner) within the separation angle and a peak value (peak_outer) of the sum signal (sum_outer) outside the separation angle are calculated.

The audio volume balance between the audio signal within the separation angle and the audio signal outside the separation angle is determined based on the audio peak value (peak_inner) of the sum signal (sum_inner) within the separation angle and the audio peak value (peak_outer) of the sum signal (sum_outer) outside the separation angle. The gain value Gi to the audio signal within the separation angle and the gain value Go to the audio signal outside the separation angle are determined based on the audio volume balance between the audio signal within the separation angle and the audio signal outside the separation angle and the audio volume balance command signal S2 from the system controller 4.

For example, the audio volume balance command signal S2 from the system controller 4 indicates that the volume ratio between the audio signal within the separation angle and the audio signal outside the separation angle is 1:1 and the ratio of the audio peak value (peak_inner) of the sum signal (sum_inner) within the separation angle and the audio peak value (peak_outer) of the sum signal (sum_outer) outside the separation angle is 1:2. In this case, the gain value Gi to the audio signal within the separation angle is 1.5 and the gain value Go to the audio signal outside the separation angle is 0.75. With this setting, the ratio of the audio peak value (peak_inner) of the sum signal (sum_inner) within the separation angle and the audio peak value (peak_outer) of the sum signal (sum_outer) outside the separation angle becomes 1:1.

The audio volume balance adjuster 23 may immediately adjust the balance using the gain value Gi=1.5 and the gain value Go=0.75. Alternatively, a transition time of 5 seconds may be permitted before the audio volume balance is completely adjusted. During the transition time, the audio volume balance is gradually adjusted so that the user comfortably adapts to the change.

When the gain value Gi to the audio signal within the separation angle and the gain value Go to the audio signal outside the separation angle are determined, care must be exercised so that the volume of the entire input signal and the volume of the entire output signal remain unchanged.

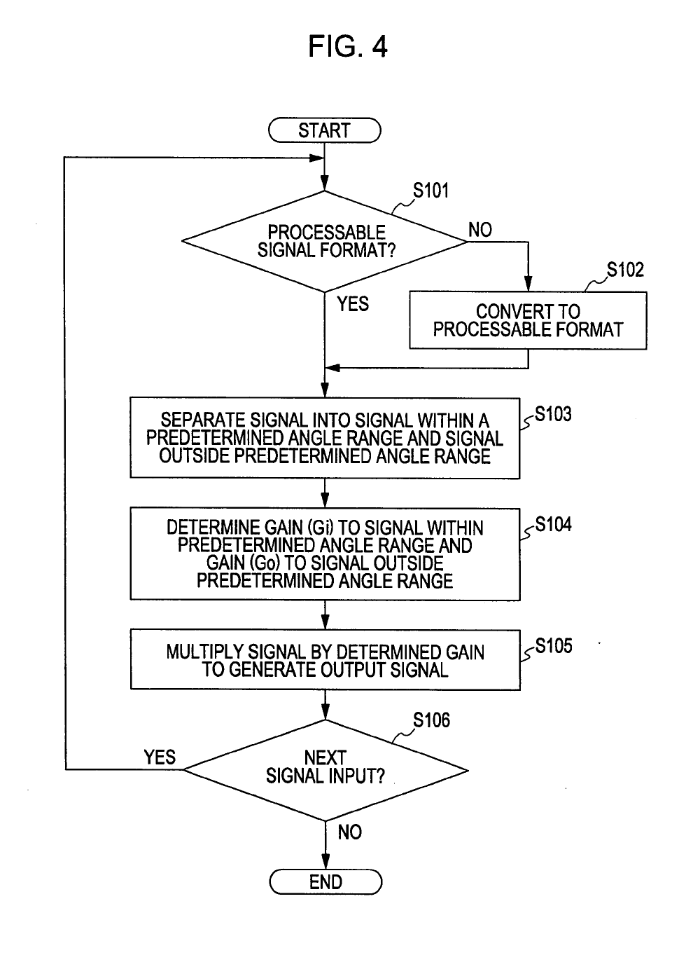

Software implementation of the first embodiment of the present invention is described below. FIG. 4 is a flowchart illustrating the process of the reproducing apparatus 100 of the first embodiment of the present invention incorporating the audio signal processor 2 of FIG. 3. FIG. 4 also applies when the first embodiment of the present invention is implemented using software.

The process of FIG. 4 is performed when the audio signal processor 2 of FIG. 3 and the system controller 4 operate in cooperation, i.e., when the audio signal recorded on the recording medium loaded on the media player 1 is reproduced in response to a play command to reproduce the audio signal received via the operation unit 5 or the remote commander 10 and the command receiver 6.

The system controller 4 in the reproducing apparatus 100 controls the audio signal processor 2, thereby determining whether the audio signal to be reproduced is in a signal format supported by own apparatus (step S101). For example, the audio signal, if compressed in accordance with MP 3 (MPEG-1 Audio Layer 3), or different in sampling frequency from the assumed signal format, cannot be processed in the current format. Such an audio signal is converted into a signal format supported by the apparatus.

If the answer to the determination in step S101 is affirmative, processing proceeds to step S103. A non-affirmative answer to the determination in step S101 means that the audio signal processor 2 cannot process the audio signal and processing proceeds to step S102.

If it is determined in step S101 that the audio signal to be reproduced is not in the signal format supported by own apparatus, the system controller 4 controls the audio signal processor 2, thereby converting the audio signal into the one in a signal format supported by own apparatus (step S102).

Subsequent to step S102, or if it is determined in step S101 that the audio signal is in the signal format supported by own apparatus, the system controller 4 supplies the separation angle command signal S1 and the audio volume balance command signal S2 to the audio signal processor 2. The audio signal processor 2 separates the audio signal into the audio signals Li and Ri within the separation angle and the audio signals Lo and Ro outside the separation angle, designated by the separation angle command signal S1 (step S103). Steps S103 is performed by the separation processor 21 in the audio signal processor 2 constructed as shown in FIG. 3.

The audio signal processor 2 measures the audio peak values (peak_inner) of the sum signal of the audio signal Li of Lch and audio signal Ri of Rch of Rch within the separation angle and the audio peak value (peak_outer) of the sum signal of the audio signal Lo of Lch and audio signal Ro of Rch outside the separation angle. In response to these values and the audio volume balance command signal S2 from the system controller 4, the gain value Gi to the audio signal Li of Lch and audio signal Ri of Rch of Rch within the separation angle and the gain value Go to the audio signal Lo of Lch and audio signal Ro of Rch outside the separation angle are determined (step S104). Step S104 is performed by the audio volume balance detector 22 in the audio signal processor 2 discussed with reference to FIG. 3.

In accordance with equation (1), the audio signal processor 2 determines the output audio signal Lex of Lch from the audio signal Li of Lch within the separation angle, the audio signal Lo of Lch outside the separation angle, the gain value Gi to the audio signal within the separation angle, and the gain value Go to the audio signal outside the separation angle. The audio signal processor 2 further determines the output audio signal Rex of Rch from the audio signal Ri of Rch within the separation angle, the audio signal Ro of Rch outside the separation angle, the gain value Gi to the audio signal within the separation angle and the gain value Go to the audio signal outside the separation angle. The audio signal processor 2 outputs the output audio signal Lex of Lch and the output audio signal Rex of Rch (step S105). Step S105 is performed by the audio volume balance adjuster 23 in the audio signal processor 2 of FIG. 3.

The output audio signals Lex and Rex thus generated are in a state that reflects personal preference, i.e., in a state that the audio volume balance between the audio signal of the sound source localized within the designated angle and the audio signal of the sound source localized outside the designated angle is adjusted in accordance with the provided command information.

The system controller 4 determines whether a next audio signal to be input to the audio signal processor 2 is present (step S106). A non-affirmative answer to the determination in step S106 means that no signal to be reproduced is present, and the process of FIG. 4 ends. An affirmative answer to the determination in step S106 means that a next audio signal to be reproduced is present. Processing returns to step S101 to repeat step S101 and subsequent steps.

The system controller 4 and the audio signal processor 2 of FIG. 3 operate in cooperation with each other, and thus determine the audio volume balance between the audio signal of the sound source localized within the designated angle and the audio signal of the sound source localized outside the designated angle, based on the separation angle (range) and information indicating the audio volume balance issued by the user. The audio volume balance is automatically adjusted to an appropriate state without the user's intervention.

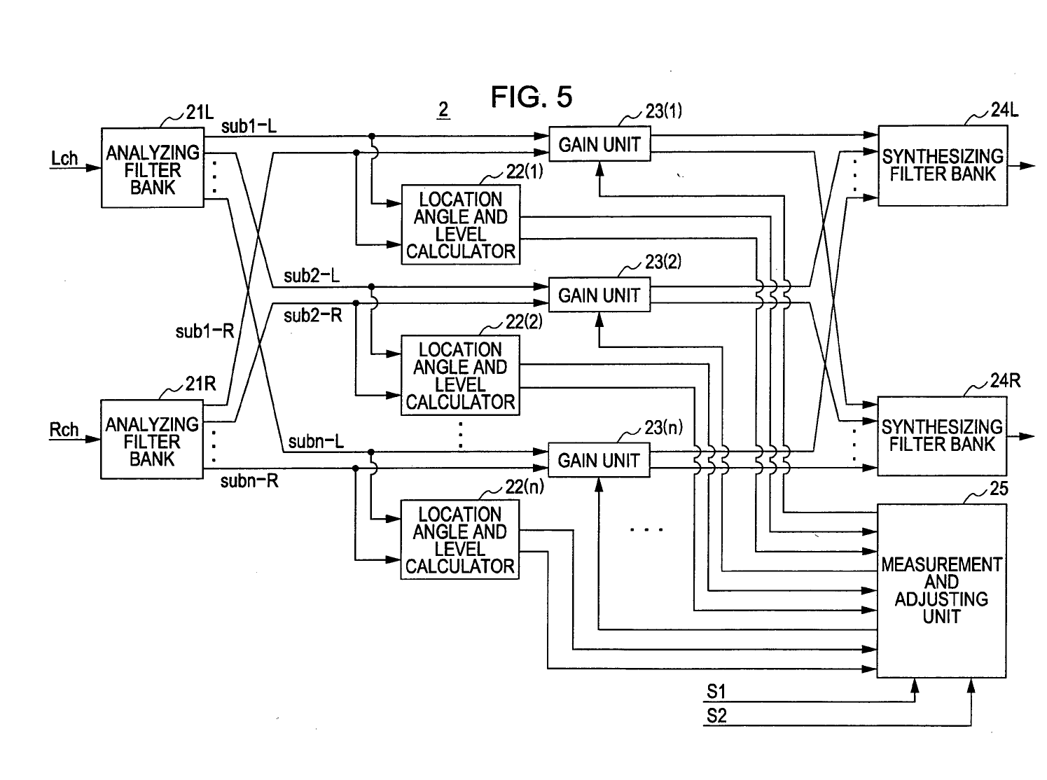

FIG. 5 is a block diagram illustrating a second configuration of the audio signal processor 2 in the reproducing apparatus 100 in accordance with the first embodiment of the present invention. The audio signal processor 2 modifies the audio volume balance using the technique proposed in Japanese Patent Application No. 2005-327237 (Serial No. 0590529003). Japanese Patent Application No. 2005-327237 discloses the technique of adjusting the volume of an audio signal of a sound source localized in an angle. A technique of adjusting the audio volume balance is combined the technique disclosed in Japanese Patent Application No. 2005-327237.

As shown in FIG. 5, the audio signal processor 2 includes an analyzing filter bank 21L of Lch receiving an input audio signal of Lch, and an analyzing filter bank 21R of Rch receiving an input audio signal of Rch. The analyzing filter bank 21L of Lch and the analyzing filter bank 21R of Rch divide the input audio signal into a plurality of frequency bands, each band having a predetermined bandwidth.

Filter bank techniques including a discrete Fourier transform (DFT) filter bank, wavelet filter bank, and quadrature mirror filter (QMF) filter bank are available to divide an input signal component into a plurality of frequency bands. A filter bank is composed of one set of an analyzing filter and a synthesizing filter. The filter bank technique is used when an input signal is processed on a per frequency band basis and on a purpose by purpose basis, and is widely used in lossy compression applications.

The analyzing filter bank 21L divides the input audio signal of Lch into n frequency bands, each band having equal bandwidths, thereby n sub bands (sub1-L, sub2-L, subn-L). The n sub band signals sub1-L through subn-L are supplied to a synthesizing filter bank 24L via respective gain units 23 (23(1) through 23(n)).

The synthesizing filter bank 24L synthesizes the n sub band signals (sub1-L through subn-L) respectively supplied from the n gain units 23(1) through 23(n), thereby reconstructing an audio signal in the original form thereof.

Similarly, the analyzing filter bank 21R divides the input audio signal of Rch into n frequency bands, thereby generating n sub band signals (sub1-R, sub2-R, . . . , subn-R). The n sub band signals sub1-R through subn-R are supplied to the synthesizing filter bank 24R via the respective gain units 23(1) through 23(n).

The synthesizing filter bank 24R synthesizes the n sub band signals (sub1-R through subn-R) respectively supplied by the gain units 23(1) through 23(n), thereby reconstructing an audio signal in the original form thereof.

The analyzing filter bank 21L and the analyzing filter bank 21R divides the input audio signal into the n frequency bands of equal bandwidth. The present invention is not limited to this arrangement. The input audio signal may be divided into a plurality of frequency bands having different bandwidths.

The sub band signals sub1-L through subn-L supplied from the analyzing filter bank 21L are respectively supplied to n location angle and level calculators 22(1) through 22(n) as shown in FIG. 5.

Similarly, the sub band signals sub1-R through subn-R generated by the analyzing filter bank 21R are respectively supplied to the n location angle and level calculators 22(1) through 22(n) as shown in FIG. 5.

The location angle and level calculators 22(1) through 22(n) receive the sub band signals sub-L of Lch and sub band signals sub-R of Rch at the respective sub bands thereof.

As will be described in detail later, the location angle and level calculators 22(1) through 22(n) calculate location angles and levels from the sub band signals sub-L of Lch and the sub band signals sub-R, and supply location angle information and level information to a gain measurement and adjusting unit 25.

The location angle and level calculator 22(1) calculates the location angle and level of the input audio signal from the sub band signal sub1-L and the sub band signal sub1-R, the location angle and level calculator 22(2) calculates the location angle and level of the input audio signal from the sub band signal sub2-L and the sub band signal sub2-R. In this way, the location angle and level calculators 22(1) through 22(n) calculate the location angles and levels from the sub band signals sub1-L through subn-L and the sub band signals sub1-R through subn-R and supply the location angles and levels to the gain measurement and adjusting unit 25. The internal structure of the location angle and level calculator 22 will be described later.

The gain measurement and adjusting unit 25 receives the location angle information and the level information from the location angle and level calculators 22(1) through 22(n), and the separation angle command signal S1 and the audio volume balance command signal S2 from the system controller 4 of FIG. 5. The gain measurement and adjusting unit 25 thus determines gains to be supplied to the gain units 23(1) through 23(n) so that an optimum audio volume balance is attained. The process of the gain measurement and adjusting unit 25 will be described later.

In response to the supplied gains, the gain units 23(1) through 23(n) adjust the gain to the sub band signal sub-L from the analyzing filter bank 21L and the gain to the sub band signal sub-R from the analyzing filter bank 21R, and supply the gain-adjusted sub band signal sub-L to the synthesizing filter bank 24L and the gain-adjusted sub band signal sub-R to the synthesizing filter bank 24R.

The synthesizing filter banks 24L and 24R synthesize the sub band signals sub1-L through subn-L and the sub band signals sub1-R through subn-R, supplied from the gain units 23(1) through 23(n), thereby reconstructing the original audio signal.

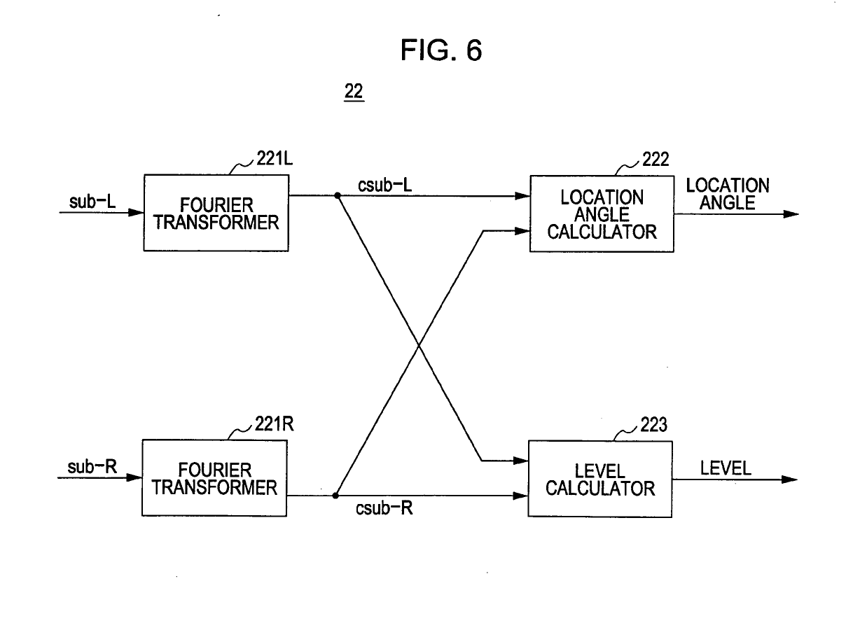

The structure and operation of the location angle and level calculator 22 in the audio signal processor 2 having the second configuration shown in FIG. 5 are described below. FIG. 6 is a block diagram illustrating the structure of the location angle and level calculator 22.

As shown in FIG. 6, the location angle and level calculator 22 includes a Fourier transformer 221L of Lch, a Fourier transformer 221R of Rch, a location angle calculator 222 and a level calculator 223.

As shown in FIG. 6, the sub band signal sub-L from the analyzing filter bank 21L of FIG. 5 is input to the Fourier transformer 221L. The Fourier transformer 221L performs a fast Fourier transform on the sub band signal sub-L. A complex sub band signal csub-L obtained through the fast Fourier transform is supplied to each of the location angle calculator 222 and the level calculator 223.

The Fourier transformer 221L is not necessary if the sub band signal sub-L has already been converted into a complex sub band form by the analyzing filter bank 21L. In such a case, the sub band signal sub-L is directly input to each of the location angle calculator 222 and the level calculator 223.

The sub band signal sub-R from the analyzing filter bank 21R is supplied to the Fourier transformer 221R for Fourier transform. A resulting complex sub band signal csub-R is supplied to each of the location angle calculator 222 and the level calculator 223. If the sub band signal sub-R has been already converted into a complex sub band form by the analyzing filter bank 21R, the Fourier transformer 221R is not necessary. The sub band signal sub-R is directly supplied to each of the location angle calculator 222 and the level calculator 223.

The location angle calculator 222 calculates a phase difference and a level ratio from the complex sub band signal csub-L and the complex sub band signal csub-R, and determines a location angle of the audio signal based on the phase difference and the level ratio. The location angle of the audio signal is supplied to the gain measurement and adjusting unit 25 of FIG. 5.

The level calculator 223 determines the level of the audio signal from the complex sub band signal csub-L and the complex sub band signal csub-R, and supplies the resulting level information of the audio signal to the gain measurement and adjusting unit 25 of FIG. 5.

Several methods are contemplated to determine the magnitude of sound. One method is described here. Let L(ω) and R(ω) represent the complex sub band signals csub-L and csub-R at time ω, and level mag(ω) of the complex sub band signal csub-L and the complex sub band signal csub-R at time ω are expressed by equation (2):

$$mag ( ω ) = \sqrt{{Re ( L ( ω ) )}^{2} + {Im ( L ( ω ) )}^{2}} + \sqrt{{Re ( R ( ω ) )}^{2} + {Im ( R ( ω ) )}^{2}} \qquad ( 2 )$$

where Re(x) represents a real part of a complex number x, and Im(x) represents an imaginary part of the complex number x.

The location angle and level calculators 22(1) through 22(n) determine the (separation) location angles and the signal levels based on the supplied sub band signals sub-L and sub-R.

The process of the gain measurement and adjusting unit 25 in the audio signal processor 2 of FIG. 5 is described below.

The gain measurement and adjusting unit 25 performs three processes as below. In a first process, the gain measurement and adjusting unit 25 determines the sum signal (sum_inner) of the levels of the audio signal of the sound source within the designated angle and the sum signal (sum_outer) of the levels of the audio signal of the sound source outside the separation angle in response to the separation angle command signal S1 and the audio volume balance command signal S2 supplied from the system controller 4. In a second process, the gain measurement and adjusting unit 25 measures the audio volume balance between the audio signal of the sound source localized within the designated angle and the audio signal of the sound source localized outside the designated angle and determines the gain value Gi to the audio signal within the designated angle and the gain value Go to the audio signal outside the designated angle. In a third process, the gain measurement and adjusting unit 25 determines the gain value of each sub band.

Referring to the location angle information of each of the sub bands from the location angle and level calculators 22(1) through 22(n) and the separation angle command signal S1 from the system controller 4 of FIG. 1, the gain measurement and adjusting unit 25 first determines whether each sub band signal is an audio signal of a sound source within the designated angle. If it is determined that the sub band signal is an audio signal of a sound source within the designated angle, the gain measurement and adjusting unit 25 adds the level value from the corresponding one of the location angle and level calculators 22(1) through 22(n) to the sum signal (sum_inner) of the levels of the audio signal within the designated angle. If it is determined that the sub band signal is an audio signal of a sound source outside the designated angle, the gain measurement and adjusting unit 25 adds the level value from the corresponding one of the location angle and level calculators 22(1) through 22(n) to the sum signal (sum_outer) of the levels of the audio signal outside the designated angle. This process is performed on the location angle information and the level information of all sub bands. The level sum (sum_inner) of the audio signal within the designated angle and the level sum (sum_outer) of the audio signal outside the designated angle are thus determined.

Several methods are contemplated to measure the audio volume balance. The same method as the one described with reference to the first configuration is employed herein. More specifically, the level sum (sum_inner) of the audio signal within the designated angle and the level sum (sum_outer) of the audio signal outside are monitored for 5 seconds. A volume peak value (peak_inner) of the level sum (sum_inner) of the audio signal within the designated angle and a volume peak value (peak_outer) of the level sum (sum_outer) of the audio signal outside are then calculated throughout the same period.

The gain measurement and adjusting unit 25 receives the volume peak value (peak_inner) of the level sum (sum_inner) of the audio signal within the designated angle and the volume peak value (peak_outer) of the level sum (sum_outer) of the audio signal outside the designated angle and the audio volume balance command signal S2 from the system controller 4 of FIG. 1, and then determines the gain value Gi to the audio signal within the predetermined angle and the gain value Go to the audio signal outside the predetermined angle.

The balance adjustment may be performed immediately after determining the gain values. Alternatively, a transition time of 5 seconds may be permitted before the audio volume balance is adjusted. During the transition time, the audio volume balance is gradually adjusted so that the user comfortably adapts to the change as in the audio signal processor 2 having the first configuration.

When the gain value Gi to the audio signal within the location angle and the gain value Go to the audio signal outside the location angle are determined, care must be exercised in the same manner as in the audio signal processor 2 having the first configuration so that the volume of the entire input signal and the volume of the entire output signal remain unchanged.

The gain value Gi is supplied to the gain units 23(1) through 23(n) if the sub band signal is the audio signal of the sound source within the designated angle, and the gain value Go is supplied to the gain units 23(1) through 23(n) if the sub band signal is the audio signal of the sound source outside the designated angle. The gain units 23(1) through 23(n) multiply the supplied sub bands by the designated gain values respectively, thereby performing gain adjustment. Finally, the synthesizing filter banks 24L and 24R synthesize the sub band signals, thereby generating an output audio signal with the audio volume balance adjusted between the audio signal within the predetermined angle and the audio signal outside the predetermined angle.

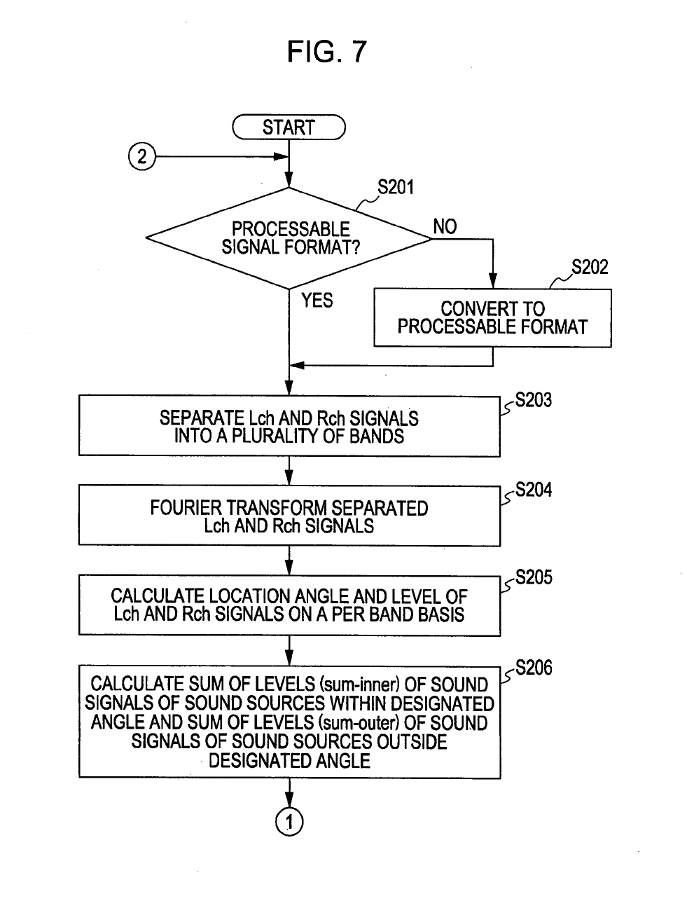

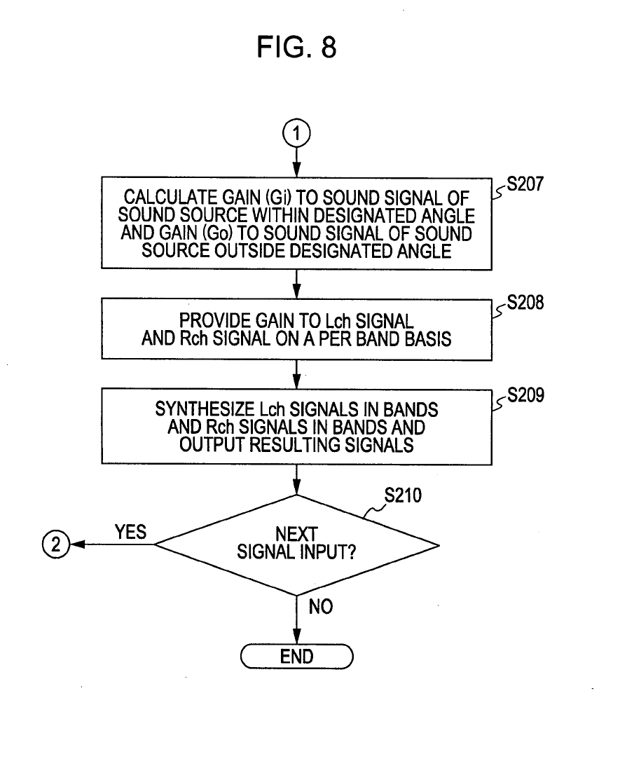

Another example of software implementation in accordance with the first embodiment is described below. FIGS. 7 and 8 are flowcharts of the process performed by the reproducing apparatus 100 in accordance with the first embodiment of the present invention discussed with reference to FIGS. 5 and 6. The flowcharts are also applicable even when the present invention is implemented using software.

The process of FIGS. 7 and 8 is performed when the audio signal processor 2 and the system controller 4 operate in cooperation, i.e., when the audio signal recorded on the recording medium loaded on the media player 1 is reproduced in response to a play command to reproduce the audio signal received via the operation unit 5 or the remote commander 10 and the command receiver 6.

The system controller 4 in the reproducing apparatus 100 controls the audio signal processor 2, thereby determining whether the audio signal to be reproduced is in a signal format supported by own apparatus (step S201). For example, the audio signal, if compressed in accordance with MP 3 (MPEG-1 Audio Layer 3), or different in sampling frequency from the assumed signal format, cannot be processed in the present format thereof. Such an audio signal is converted into a signal format supported by the apparatus.

If the answer to the determination in step S201 is affirmative, processing proceeds to step S203. A non-affirmative answer to the determination in step S201 means that the audio signal processor 2 cannot process the audio signal and processing proceeds to step S202.

If it is determined in step S201 that the audio signal to be reproduced is not in the signal format supported by own apparatus, the system controller 4 controls the audio signal processor 2, thereby converting the audio signal into the one in a signal format supported by own apparatus (step S202).

Subsequent to step S202, or if it is determined in step S201 that the audio signal is in the signal format supported by own apparatus, the system controller 4 supplies the separation angle command signal S1 and the audio volume balance command signal S2 to the audio signal processor 2. The audio signal processor 2 separates each of the audio signal of Lch and the audio signal of Rch into a plurality frequency bands (step S203).

Step S203 corresponds to the operation in which the analyzing filter bank 21L and the analyzing filter bank 21R in the audio signal processor 2 of FIG. 5 divides each of the audio signal of Lch and the audio signal of Rch into the n frequency bands, thereby generating the sub band signals sub1-L through subn-L and the sub band signals sub1-R through subn-R.

The audio signal processor 2 Fourier transforms the divided Lch audio signals and the divided Rch audio signals (step S204). Step S204 corresponds to the operation in which the Fourier transformer 221L and the Fourier transformer 221R in each of the location angle and level calculators 22(1) through 22(n) Fourier transform the input sub band signal sub-L and the input sub band signal sub-R.

If the sub band signals sub-L and sub-R are already converted in the complex sub band form in step S203 as previously discussed, step S204 is not necessary. Processing proceeds to step S205 with step S204 skipped.

The audio signal processor 2 calculates the location angle and the level of the Lch audio signal and the Rch audio signal on a per divided band (frequency band) basis (step S205). Step S205 corresponds to the operation in which the location angle calculator 222 and the level calculator 223 in each of the location angle and level calculators 22(1) through 22(n) of FIG. 6 calculate the location angle and the level of the sub band signal sub-L and the sub band signal sub-R on each sub band.

The audio signal processor 2 compares the location angle determined on a per band basis with the separation angle command signal S1 from the system controller 4, determines level sum (sum_inner) of the audio signal within the designated angle and the level sum (sum_outer) of the audio signal outside the designated angle (step S206). Step S206 corresponds to one of the processes performed by the gain measurement and adjusting unit 25 in the audio signal processor 2 of FIG. 5.

Processing proceeds to step S207 of FIG. 8. The audio signal processor 2 determines the gain value Gi to the audio signal within the designated angle and the gain value Go to the audio signal outside the designated angle (step S207). In step S207, the audio signal processor 2 uses the level sum (sum_inner) of the audio signal within the designated angle and the level sum (sum_outer) of the audio signal outside the designated angle, determined in step S206, and the audio volume balance command signal S2 from the system controller 4.

The audio signal processor 2 outputs the gain value Gi if each of the sub band signal sub-L and the sub band signal sub-R is the audio signal of the sound source within the designated angle on each sub band, and the audio signal processor 2 outputs the gain value Go if each of the sub band signal sub-L and the sub band signal sub-R is the audio signal of the sound source outside the designated angle on each sub band (step S208). Step S208 corresponds to the operation in which the gain value Gi or the gain value Go output from the gain measurement and adjusting unit 25 in the audio signal processor 2 of FIG. 6 is supplied to the gain units 23(1) through 23(n) in order to gain adjust the respective sub band signal.

The audio signal processor 2 synthesizes the Rch audio signal and the Rch audio signal at each band and then outputs the resulting signal (step S209). The synthesizing filter bank 24L of FIG. 5 receives and synthesizes the Lch audio signals of the bands supplied from the gain units 23(1) through 23(n), and outputs the synthesized signal. The synthesizing filter bank 24R of FIG. 5 receives and synthesizes the Rch audio signals of the bands supplied from the gain units 23(1) through 23(n), and outputs the synthesized signal.

As previously discussed, the synthesizing filter bank 24L and the synthesizing filter bank 24R output the output audio signal Lex and the output audio signal Rex, respectively. The output audio signals Lex and Rex allow the audio signal to be reproduced at the audio volume balance between the audio signal of the sound source localized within the angle designated by the separation angle command signal S1 and the audio signal of the sound source localized outside the angle designated by the separation angle command signal S1. The audio volume balance thus reflects the preference of the user.

The system controller 4 determines whether a next audio signal to be input to the digital-to-analog converter 3 is present (step S210). If the answer to the determination in step S210 is non-affirmative, no next signal is present, and the process ends. If the answer to the determination in step S210 is affirmative, a next audio signal to be processed is present. The system controller 4 returns to step S201 to repeat step S201 and subsequent steps.

The audio signal processor 2 of FIG. 5 and the system controller 4 operate in cooperation, thereby determining the audio volume balance between the audio signal of the sound source localized within the designated angle and the audio signal of the sound source localized outside the designated angle based on the information indicating the separation angle and the audio volume balance input by the user. The audio signal processor 2 automatically adjusts the audio volume balance to an appropriate value without the user's intervention.

In the case of the audio signal processor 2 of FIG. 3 having the first configuration, the audio volume balance adjuster 23 adjusts the audio volume balance in accordance with equation (1), thereby generating and outputting the Lch audio signal and the Rch audio signal. Another audio volume balance adjustment method may be used. For example, optionally, an equation different from equation (1) may be used.

In the audio signal processor 2 of FIG. 3 having the first configuration, the separation processor 21 outputs two channel audio signals Li and Ri within the designated angle. The present invention is not limited to this arrangement. The number of channels may be at least one.

In the audio signal processor 2 of FIG. 3 having the first configuration, a 5.1 channel input may be used. Since the input channels are already separated, the separation processor 21 is not necessary and can be eliminated.

In the audio signal processor 2 of FIG. 5 having the second configuration, the level calculator 223 determines the level of sound using equation (2). Another alternative method can be used. The input to the level calculator 223 is a complex sub band signal. Alternatively, the sub band signal may be used to determine the level of sound.

The reproducing apparatus 100 of the first embodiment of the present invention performs the audio volume balance adjustment process. The audio volume balance adjustment process illustrated in the flowchart of FIG. 4 or in the flowcharts of FIGS. 7 and 8 is mainly performed using hardware, namely, the audio signal processor 2. The present invention is not limited to this arrangement. As previously discussed, each of the process of FIG. 4 and the process of FIGS. 7 and 8 in whole or in part may be performed using software.

In such a case, a program to be mainly executed by the system controller 4 is produced, and the system controller 4 controls the audio signal processor 2 to execute the process.

Alternatively, the audio signal processor 2 may be a microcomputer including a CPU, a ROM and a RAM. A program for executing the process of FIG. 4 or the process of FIGS. 7 and 8 is stored on the ROM, and then the audio signal processor 2 executes the program.

In the above discussion, the audio volume balance is monitored for a predetermined period (5 seconds, for example), and the audio volume peak value or the sum of levels expressed by equation (2) are used. An average value of decibels representing the level of sound, or an average of absolute values of samples of PCM (pulse code modulation) signals may be used instead of the audio volume peak value.

In accordance with the first embodiment of the present invention, the transition time for causing the audio volume balance to vary (5 seconds, for example) is permitted. The transition time may not be necessary. The audio volume balance may be adjusted immediately. Alternatively, a relatively long transition time, for example, 2 minutes may be set to allow the audio volume balance to vary gradually with time.

In the first embodiment of the present invention, the number of input audio signal channels and the number of output audio signal channels are respectively two. The present invention is not limited to two channels. The number of channels is at least two. Furthermore, the number of input channels and the number of output channels may be different. For example, the number of input channels may be two, and the number of output channels may be four.

Rather than adjusting the audio volume balance, the reproducing apparatus 100 may adjust the audio volume balance in hearing sense, by processing the audio signal. For example, the reproducing apparatus 100 may perform a signal processing operation so that the audio signal within a predetermined location angle range is localized to a location near to the user, or perform a signal processing operation so that the audio signal within a predetermined location angle range is localized to a location far from the user. Furthermore, the reproducing apparatus 100 may combine these two methods.

The audio volume balance between a signal within a predetermined location angle range and a signal outside the predetermined location angle range may be superimposed on audio data. The audio volume balance may be recorded as data incidental to audio data together with time information on the recording medium or the EEPROM of the reproducing apparatus 100, each also recording the audio data. During playing, the audio volume balance is adjusted based on these pieces of information.

In response to the separation angle and the audio volume balance received from the user, the reproducing apparatus 100 of the first embodiment of the present invention determines the audio volume balance between the audio signal of the sound source localized within the designated angle and the audio signal of the sound source localized outside the designated angle. By automatically adjusting the audio volume balance, the reproducing apparatus 100 keeps the audio volume balance at an appropriate level without the user's intervention.

### Second Embodiment

A second embodiment of the present invention is described below. As the first embodiment of the present invention, the second embodiment is applied to an apparatus, a method and a program for reproducing an audio signal.

A reproducing apparatus 200 of the second embodiment of the present invention determines the audio volume balance between the audio signal of the sound source localized within the designated angle and the audio signal of the sound source localized outside the designated angle in response to the type and the audio volume balance of the sound source from the user. By automatically adjusting the audio volume balance, the reproducing apparatus 200 keeps the audio volume balance at an appropriate level without the user's intervention.

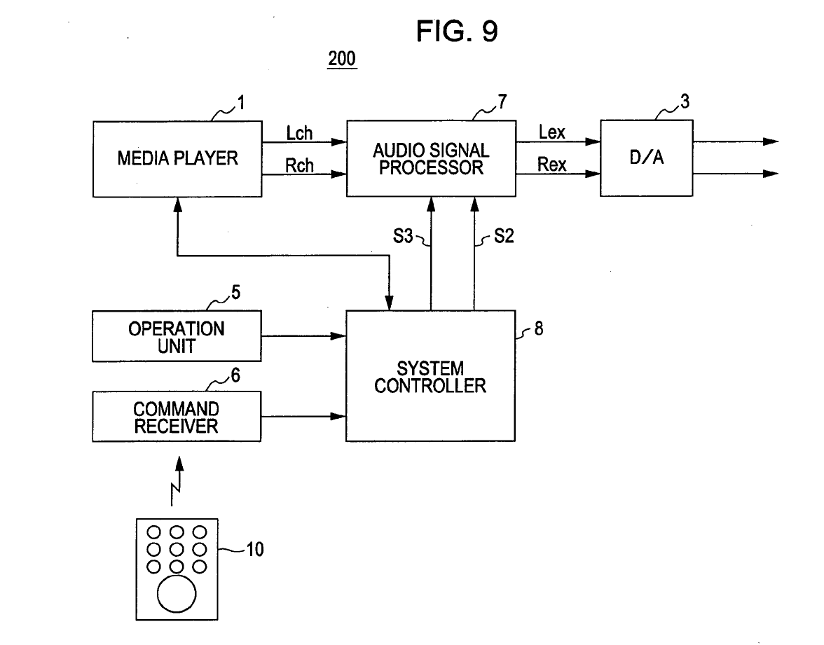

FIG. 9 is a block diagram illustrating the reproducing apparatus 200 of the second embodiment of the present invention. In FIG. 2, elements of the reproducing apparatus 200 of the second embodiment identical to those illustrated in FIG. 1 are designated with the same reference numerals and the discussion thereof is omitted herein.

As the reproducing apparatus 100 of the first embodiment shown in FIG. 1, the reproducing apparatus 200 of the second embodiment shown in FIG. 9 includes the media player 1, the digital-to-analog converter 3, the operation unit 5, the command receiver 6, and the audio signal processor 7. The reproducing apparatus 200 can also be remote controlled by the remote commander 10.

The structure and operation of the audio signal processor 7 and the operation of the system controller 8 in the reproducing apparatus 200 of the second embodiment are respectively different from the structure and operation of the audio signal processor 7 and the operation of the system controller 4 in the reproducing apparatus 100 of the first embodiment. In terms of structure, the system controller 8 is a microcomputer identical to the system controller 4 in the reproducing apparatus 100 of the first embodiment of FIG. 1, i.e., includes the CPU 41, the ROM 42, the RAM 43, the EEPROM 44, and the CPU bus 45 that interconnects all these elements.

In the reproducing apparatus 200 of the second embodiment as well, the audio signal processor 7 is supplied with the audio signal of Lch and the audio signal of Rch reproduced by the media player 1. In response to the audio signal of Lch and the audio signal of Rch supplied from the media player 1 and a sound source type command signal S3 and an audio volume balance command signal S2 from the system controller 8 to be discussed later, the audio signal processor 7 performs a predetermined audio signal process on each of the audio signal of the designated sound source and the audio signal of the other sound source. The audio signal Lex of Lch and the audio signal Rex, each having undergone the audio signal process, are supplied to the digital-to-analog converter 3. The audio signal processor 7 in the reproducing apparatus 200 of the second embodiment will be described in detail later.

The digital-to-analog converter 3 digital-to-analog converts the audio signals Lex and Rex from the audio signal processor 7 and outputs analog output audio signals of Lch and Rch.

As the remote commander 10 of the reproducing apparatus 100 of the first embodiment, the remote commander 10 of the reproducing apparatus 200 of the second embodiment includes the controls 10a, 10b, 10c and 10d for issuing direction commands. By operating the right key 10a or the left key 10b on the reproducing apparatus 200 of the second embodiment, the user enters a command input designating to the media player 1 the type of the sound source to separated. By operating the up key 10c and the down key lad on the reproducing apparatus 200 of the second embodiment, the user enters to the reproducing apparatus 200 an audio volume balance command between the audio signal of the sound source and the audio signal of the other sound source.

The system controller 8 generates the sound source type command signal S3 to be supplied to the audio signal processor 7, in response to the command signal transmitted from the remote commander 10 with the user operating the right key 10a and the left key 10b on the remote commander 10 and received via the command receiver 6. The sound source type command signal S3 is information indicating the type of the sound source input in response to the user operation on the right key 10a and the left key 10b.

The system controller 8 generates the audio volume balance command signal S2 to be supplied to the audio signal processor 7, in response to the command signal transmitted from the remote commander 10 with the user operating the up key 10c and the down key 10d on the remote commander 10 and received via the command receiver 6. As in the reproducing apparatus 100 of the first embodiment, the audio volume balance command signal S2 is information indicating the audio volume balance input in response to the user operation on the up key 10c and the down key 10d.

The reproducing apparatus 200 of the second embodiment determines the audio volume balance between the audio signal of the designated sound source and the audio signal of the other sound source in response to the sound source type command and the audio volume balance command input on the remote commander 10 by the user. The reproducing apparatus 200 automatically adjusts the audio volume balance, thereby keeping the audio volume balance to an appropriate level without the user's intervention. The sound source type command and the audio volume balance command may be stored on the EEPROM of the system controller 8, and repeatedly used during playing of the audio signal.

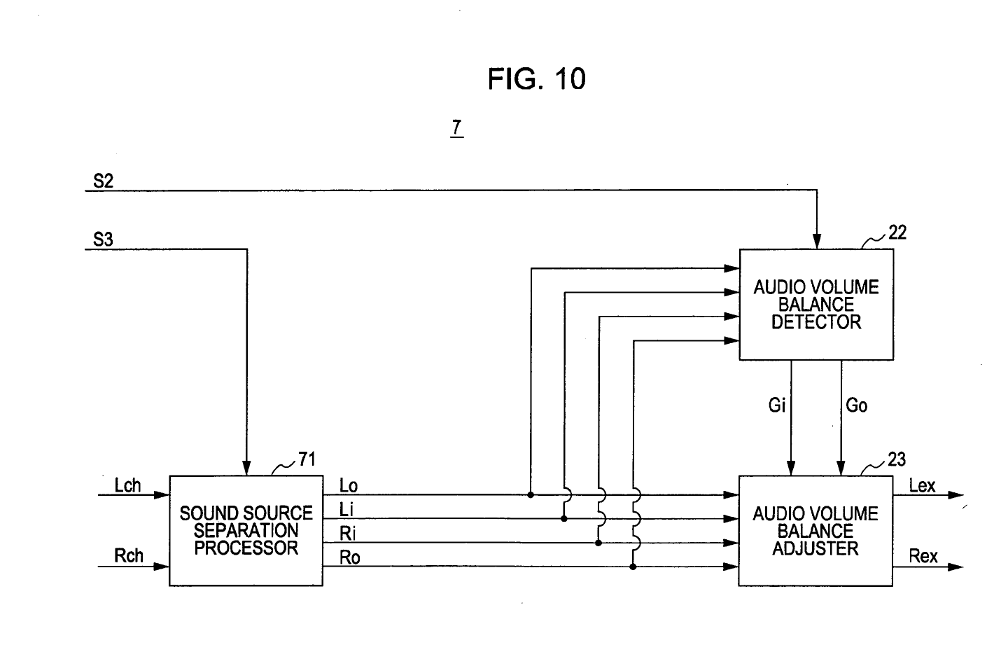

The structure and operation of the audio signal processor 7 in the reproducing apparatus 200 of the second embodiment is described below. FIG. 10 is a block diagram illustrating the audio signal processor 7 of the second embodiment. In FIG. 10, elements identical to those used in the audio signal processor 2 of the first embodiment discussed with reference to FIG. 3 are designated with the same reference numerals and the detailed discussion thereof is omitted herein.

As shown in FIG. 10, the audio signal processor 7 in the reproducing apparatus 200 of the second embodiment includes a sound source separation processor 71, an audio volume balance detector 22 and an audio volume balance adjuster 23. As shown in FIG. 10, the sound source separation processor 71 receives the audio signal of Lch and the audio signal of Rch.

Upon receiving the sound source type command signal S3 from the system controller 8 of FIG. 9, the sound source separation processor 71 separates the received audio signals into audio signals Li and Ri of the designated sound source and audio signals Lo and Ro of the other sound source, and supplies the separated audio signals to each of the audio volume balance detector 22 and the audio volume balance adjuster 23.

The sound source separation processor 71 may have any circuit arrangement as long as the circuit has the function of separating the input audio signal into the audio signal of the designated sound source and the audio signal of the other sound source. For example, when a human voice is designated as a type of sound source, a technique for discriminating the input signal between the human voice and non-human sound may be employed.

More specifically, a plurality of pieces of audio model data is stored on a memory on the audio signal processor 7 or on a memory on the system controller 8. By matching the input audio signal (input acoustic signal) with the audio model data, a score for determining whether the input audio signal is a human voice is calculated. The score is corrected with a signal-to-noise (S/N) ratio estimated for the input audio signal, and a determination step is performed as to whether the input audio data is a human voice or not using the corrected score. In this way, the input audio signal is discriminated between a human-voice portion or a non-human-voice portion. For example, by preparing audio model data of a male voice and audio model data of a female voice, a human voice can be discriminated between a male voice portion and a female voice portion.

Not only the human voice but also sound source model data of a variety of musical instruments may be stored. Music data to be reproduced (input audio signal) may be matched with the sound source model data, and an audio signal of a portion of a target musical instrument may thus be separated from an audio signal of other musical instruments. The sound source separation processor 71 can thus be constructed of a memory for storing a variety of pieces of sound source model data, an input audio signal (input acoustic signal), a matching unit for calculating a similarity between the input audio signal and the sound source model data by matching these signals, and a separator for separating the audio signal in response to the calculated similarity.

Each of the audio volume balance detector 22 and the audio volume balance adjuster 23 is supplied with the audio signal Li of a target sound source and the audio signal Lo of the other sound source in the audio signal of Lch, the audio signal Ri of the target sound source and the audio signal Ro of the other sound source in the audio signal of Rch.

As described with reference to FIG. 3, the audio volume balance detector 22 measures the audio volume balance between the target audio signal and the other audio signal, determines the gain value Gi to the target audio signal and the gain value Go to the audio signal other than the target audio signal in response to the audio volume balance command signal S2 from the system controller 8, and supplies the determined gain values Gi and Go to the audio volume balance adjuster 23.

More specifically, as shown in FIG. 10, the audio volume balance detector 22 receives the audio signal Li from the target sound source on Lch, the audio signal Ri on Rch from the target audio signal, the audio signal Lo on Lch from the sound source other than the target audio signal, and the audio signal Ro on Rch from the sound source other than target audio signal separated by the sound source separation processor 71. The audio volume balance detector 22 then measures the audio volume balance between the audio signal of the target sound source and the audio signal of the sound source other than the target sound source. The audio volume balance detector 22 then determines the gain value Gi to the audio signal of the target sound source and the gain value Go to the audio signal of the target sound source other than the target sound source in response to the audio volume balance command signal S2 from the system controller 8 so that the audio signal of the target sound source and the audio signal of the other sound source have an appropriate balance. The audio volume balance detector 22 then supplies the gain values Gi and Go to the audio volume balance adjuster 23.

As previously discussed with reference to FIG. 3, the audio volume balance adjuster 23 multiplies the audio signal of the target sound source and the audio signal of the other sound source by the gain values Gi and Go from the audio volume balance detector 22, respectively, thereby adjusting gain, and outputting the gain adjusted output audio signals Lex and Rex.

More specifically, as shown in FIG. 10, the audio volume balance adjuster 23 receives the audio signal Li from the target sound source on Lch, the audio signal Ri on Rch from the target audio signal, the audio signal Lo on Lch from the sound source other than the target audio signal, the audio signal Ro on Rch from the sound source other than target audio signal separated by the sound source separation processor 71, and the gain value Gi to the audio signal of the target sound source and the gain value Go to the audio signal of the target sound source other than the target sound source from the audio volume balance detector 22. The audio volume balance adjuster 23 performs a calculation operation of equation (1), thereby generating and outputting the output audio signal Lex of Lch and the output audio signal Rex of Rch.

The reproducing apparatus 200 determines the audio volume balance between the audio signal of the target sound source and the audio signal of the other sound source in response to the sound source type command and the audio volume balance command input on the remote commander 10 by the user. The reproducing apparatus 200 automatically adjusts and keeps the audio volume balance to an appropriate level without the user's intervention.

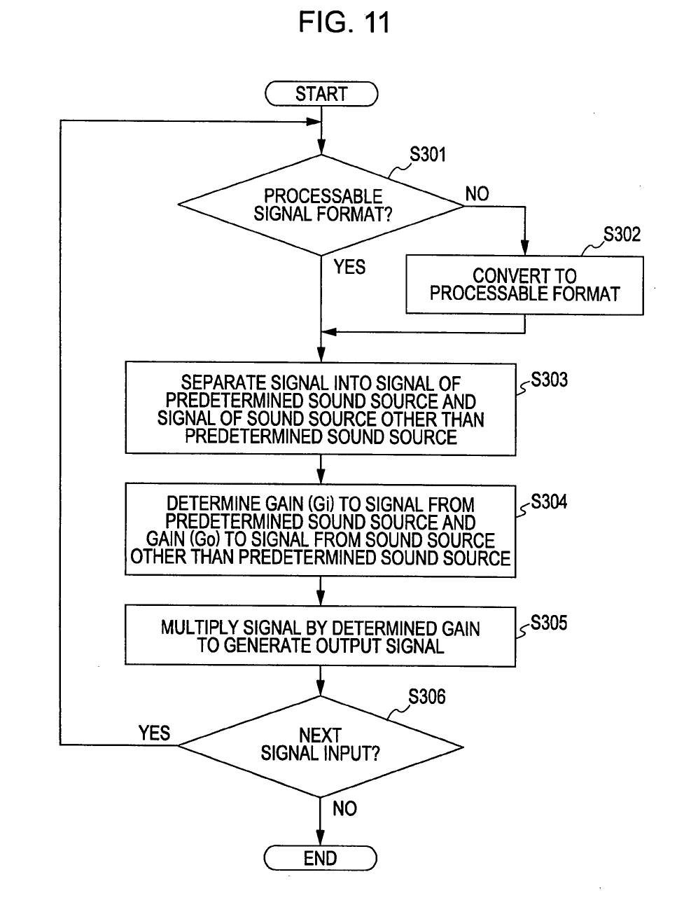

Implementation of software in accordance with the second embodiment of the present invention is described below. FIG. 11 is a flowchart illustrating the process of the reproducing apparatus 200 of the second embodiment, mainly performed by the audio signal processor 7. The flowchart of FIG. 11 is also applicable if the second embodiment of the present invention is embodied using software.

The process of FIG. 11 is performed when the audio signal processor 7 of FIG. 10 and the system controller 8 operate in cooperation, i.e., when a play command to reproduce an audio signal recorded on a recording medium loaded on the media player 1 is received from the operation unit 5 or the remote commander 10 and the command receiver 6. Steps S301 and S302 of FIG. 11 respectively correspond to steps S101 and S102 of FIG. 4 in accordance with the first embodiment.

The system controller 8 in the reproducing apparatus 200 controls the audio signal processor 2, thereby determining whether the audio signal to be reproduced is in a signal format supported by own apparatus (step S301). For example, the audio signal, if compressed in accordance with MP 3 (MPEG-1 Audio Layer 3), or different in sampling frequency from the assumed signal format, cannot be processed in the current format thereof. Such an audio signal is converted into a signal format supported by the apparatus.

If it is determined in step S301 that the audio signal to be reproduced is not in the signal format supported by own apparatus, the system controller 8 controls the audio signal processor 2, thereby converting the audio signal into the one in a signal format supported by own apparatus (step S302).

Subsequent to step S302, or if it is determined in step S301 that the audio signal is in the signal format supported by own apparatus, the system controller 8 supplies the sound source type command signal S3 and the audio volume balance command signal S2 to the audio signal processor 2. The audio signal processor 7 separates the audio signal into the audio signals Li and Ri of the sound source designated by the sound source type command signal S3 and the audio signals Lo and Ro of the sound source other than the sound source designated by the sound source type command signal S3′ (step S303). Step S130 is performed by the sound source separation processor 71 in the audio signal processor 7 constructed as shown in FIG. 10.

The audio signal processor 7 measures the audio peak values (peak_inner) of the sum signal of the audio signal Li of Lch and audio signal Ri of Rch of Rch within the predetermined angle and the audio peak value (peak_outer) of the sum signal of the audio signal Lo of Lch and audio signal Ro of Rch outside the predetermined angle. In response to these values and the audio volume balance command signal S2 from the system controller 8, the gain value Gi to the audio signal Li of Lch and audio signal Ri of Rch of Rch within the separation angle and the gain value Go to the audio signal Lo of Lch and audio signal Ro of Rch outside the separation angle are determined (step S304). Step S304 is performed by the audio volume balance detector 22 in the audio signal processor 7 discussed with reference to FIG. 10.

In accordance with equation (1), the audio signal processor 7 determines the output audio signal Lex of Lch from the audio signal Li of Lch of the target sound source, the audio signal Lo of Lch of the sound source other than the target sound source, the gain value Gi to the audio signal of the target sound source, and the gain value Go to the audio signal of the sound source other than the target sound source. The audio signal processor 7 further determines the output audio signal Rex of Rch from the audio signal Ri of Rch of the target sound source, the audio signal Ro of Rch of the sound source other than the target sound source, the gain value Gi to the audio signal of the target sound source and the gain value Go to the audio signal of the sound source other than the target sound source. The audio signal processor 7 outputs the output audio signal Lex of Lch and the output audio signal Rex of Rch (step S305). Step S305 is performed by the audio volume balance adjuster 23 in the audio signal processor 7 of FIG. 10.

The output audio signals Lex and Rex thus generated are in a state that reflects personal preference, i.e., in a state that the audio volume balance between the audio signal of the target sound source and the audio signal of the sound source other than the target sound source is adjusted in accordance with the provided command information.

The system controller 8 determines whether a next audio signal to be input to the audio signal processor 7 is present (step S306). A non-affirmative answer to the determination in step S306 means that no signal to be reproduced is present, and the process of FIG. 11 ends. An affirmative answer to the determination in step S306 means that a next audio signal to be reproduced is present. Processing returns to step S301 to repeat step S301 and subsequent steps.

The system controller 8 and the audio signal processor 7 of FIG. 10 operate in cooperation with each other, and thus determine the audio volume balance between the audio signal of the target sound source and the audio signal of the sound source other than the target sound source, based on the information indicating the type of the target sound source and the audio volume balance issued beforehand by the user. The audio volume balance is automatically adjusted to and maintained at an appropriate level without the user's intervention.

In response to the audio signal type command and the audio volume balance command from the user, the reproducing apparatus 200 of the second embodiment determines the audio volume balance between the audio signal of the target sound source and the audio signal of the other sound source. The reproducing apparatus 200 automatically adjusts and maintains the audio volume balance to an appropriate level without the need for the user's intervention.

### Third Embodiment

In accordance with the first and second embodiments, the present invention is applied to the reproducing apparatus for reproducing the audio signal. The present invention is applicable not only to the reproducing apparatus but also to a recording apparatus. In a third embodiment, the present invention is applied to a recording and reproducing apparatus 300.

In the recording and reproducing apparatus 300 of the third embodiment, the reproducing apparatus 100 of the first embodiment discussed with reference to FIGS. 1 through 8 is applied to a recording system. The recording and reproducing apparatus 300 receives the separation angle command and the audio volume balance command from the user relating to the audio signal picked up and then to be recorded on a recording medium. The recording and reproducing apparatus 300 determines the audio volume balance between audio signal of the sound source localized within the designated angle and the audio signal of the sound source localized outside the designated angle. The recording and reproducing apparatus 300 can thus automatically adjust the audio volume balance and then record the audio signal at an audio volume balance without the need for the user's intervention in each time.

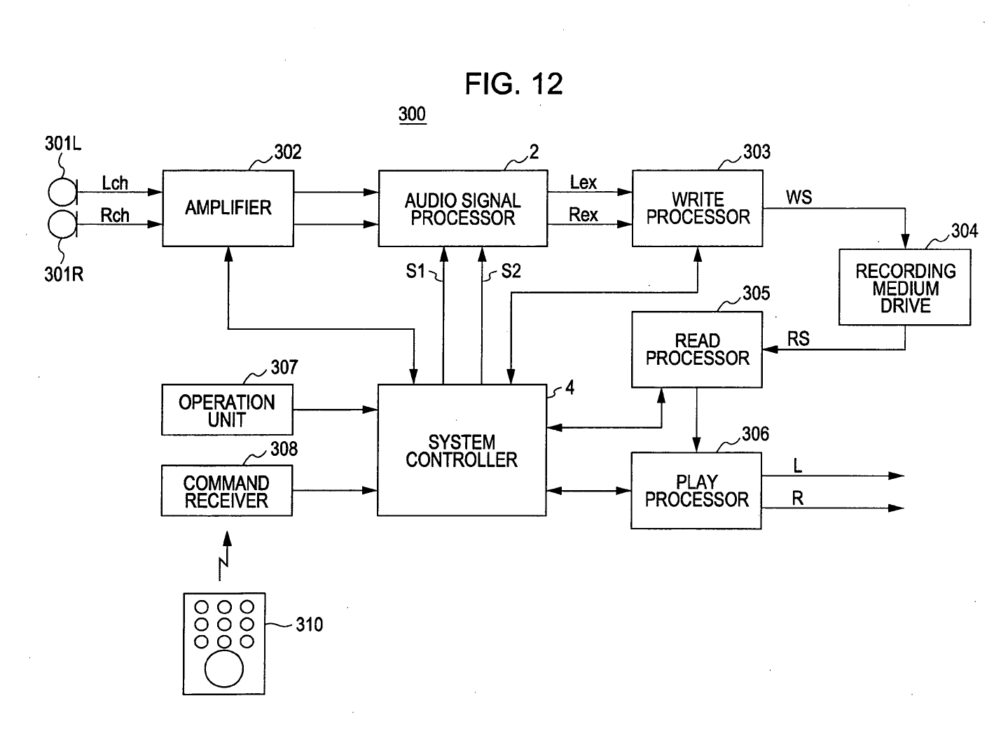

FIG. 12 is a block diagram illustrating the recording and reproducing apparatus 300 of the third embodiment of the present invention. As shown in FIG. 12, elements identical to those of the reproducing apparatus 100 illustrated in FIG. 1 are designated with the same reference numerals and the discussion thereof is omitted herein.

As shown in FIG. 12, the recording and reproducing apparatus 300 of the third embodiment includes left and right microphones 301L and 301R, an amplifier 302, a write processor 303, a recording medium drive 304, a read processor 305, a play processor 306, an operation unit 307, a command receiver 308, a remote commander 310, an audio signal processor 2 and a system controller 4.

As previously discussed, the audio signal processor 2 and the system controller 4 are identical in structure and operation to the counterparts thereof in the reproducing apparatus 100 of FIG. 1 of the first embodiment. The operation unit 307, the command receiver 308 and the remote commander 310 are also identical in structure and operation to the operation unit 5, the command receiver 6 and the remote commander 10 in the reproducing apparatus 100 of FIG. 1 of the first embodiment. The operation unit 307, the command receiver 308 and the remote commander 310 also receive a record command to record the audio signal and an adjustment command to perform a variety of adjustments on the audio signal to be recorded.

In the recording and reproducing apparatus 300 of the third embodiment, the system controller 4 receives the separation angle command and the audio volume balance command from the user via the remote commander 310 and the command receiver 308. During recording operation of the audio signal, the system controller 4 generates the separation angle command signal S1 and the audio volume balance command signal S2 in response to the commands input by the user, and then supplies these signals S1 and S2 to the audio signal processor 2.

The sounds picked up by the left and right microphones 301L and 301R are converted into an Lch audio signal and an Rch audio signal as electrical signals. The Lch audio signal and the Rch audio signal are supplied to the amplifier 302 for amplification. The amplified Lch audio signal and Rch audio signal are then supplied to the audio signal processor 2.

As previously discussed in connection with the reproducing apparatus 100 of the first embodiment, the audio signal processor 2 separates each of the Lch audio signal and the Rch audio signal into the audio signal of the sound source within the designated angle and the audio signal of the sound source outside the designated angle in response to the separation angle command signal S1 while measuring the audio volume level of each of the audio signal of the sound source within the designated angle and the audio signal of the sound source outside the designated angle.

The audio signal processor 2 determines the gain value Gi to the audio signal within the predetermined angle and the gain value Go to the audio signal outside the predetermined angle, based on the audio volume level of the audio signal of the sound source within the designated angle, the audio volume level of the audio signal of the sound source outside the designated angle, and the audio volume balance command signal S2 from the system controller 4.

The audio signal processor 2 gain adjusts the audio signal within the predetermined angle using the gain value Gi, and gain adjusts the audio signal outside the predetermined angle using the gain value Go. The output audio signal Lex of Lch and the output audio signal Rex of Rch are thus generated and output.

The output audio signal Lex of Lch and the output audio signal Rex of Rch output from the audio signal processor 2 are supplied to the write processor 303. The write processor 303 converts the audio signals Lex and Rex into signals WS in a format to be recorded on the recording medium. The signals WS are then supplied to the recording medium drive 304 to be recorded on a predetermined recording medium loaded on the recording medium drive 304.

The recording medium drive 304 may use one selected from a variety of types of recording medium. For example, the recording medium drive 304 may be one of an optical disk drive using one of an optical recording disk (such as a compact disk (CD), a digital versatile disk (DVD), and blu-ray disk), a magneto-optical disk drive using a magneto-optical disk (such as Mini Disk (MD (Registered Trademark))), a magnetic disk drive using a magnetic disk (such as a hard disk), and a semiconductor memory drive using a semiconductor memory.

The recording and reproducing apparatus 300 of the third embodiment adjusts the audio signals picked up by the microphones 301L and 301R so that the audio signal of the sound source within the designated location angle and the audio signal of the sound source outside the designated location angle are at a designated audio volume balance, and records the adjusted audio signal on the recording medium of the recording medium drive 304.

The audio signal recorded on the recording medium of the recording medium drive 304 can be read by the read processor 305 controlled by the system controller 4. The audio signal RS read from the recording medium by the read processor 305 is supplied to the play processor 306. The play processor 306 separates the supplied audio signal into the Lch audio signal and the Rch audio signal. The Lch audio signal and the Rch audio signal are then amplified into output audio signals L and R. The output audio signals L and R are supplied to loudspeakers that emit sounds responsive to the output audio signals L and R.

The audio signal recorded on the recording medium of the recording medium drive 304 is the one that has been audio volume balance adjusted by the audio signal processor 2 in response to the separation angle command signal S1 and the audio volume balance command signal S2 from the system controller 4. More specifically, the audio signal recorded on the recording medium of the recording medium drive 304 has been adjusted to satisfy the user's preference in the audio volume balance between the audio signal within the predetermined angle and the audio signal outside the predetermined angle. During playing, the audio signal is simply reproduced, and the user can enjoy listening to the audio signal at the audio volume balance satisfying the user's preference. In other words, the user is freed from the audio volume balance adjustment during playing.

In the recording and reproducing apparatus 300 of the third embodiment, the audio signal processor 2 may be constructed as described with reference to FIG. 3, or constructed as described with reference to FIG. 5. If the audio signal processor 2 has the same structure as the one illustrated in FIG. 3, the process performed by the audio signal processor 2 and the system controller 4 in cooperation becomes the one of FIG. 4. If the audio signal processor 2 has the same structure as the one illustrated in FIG. 5, the process performed by the audio signal processor 2 and the system controller 4 in cooperation becomes the one of FIGS. 7 and 8.

### Fourth Embodiment

As in the third embodiment, a fourth embodiment is a recording and reproducing apparatus 400 implementing the present invention.

The recording and reproducing apparatus 400 of the fourth embodiment is the one that implements the present invention in a recording system as the reproducing apparatus 200 of the second embodiment discussed with reference to FIGS. 9-11 implements the present invention in the recording system. In response to the sound source type command and the audio volume balance command from the user, the recording and reproducing apparatus 400 of the fourth embodiment of the present invention determines the audio volume balance of the audio signal, picked up and to be recorded on the recording medium, between the audio signal of the designated sound source and the audio signal of the other sound source. The recording and reproducing apparatus 400 automatically adjusts the audio volume balance and then continuously records the audio signal at an appropriate audio volume balance without the need for the user's intervention.

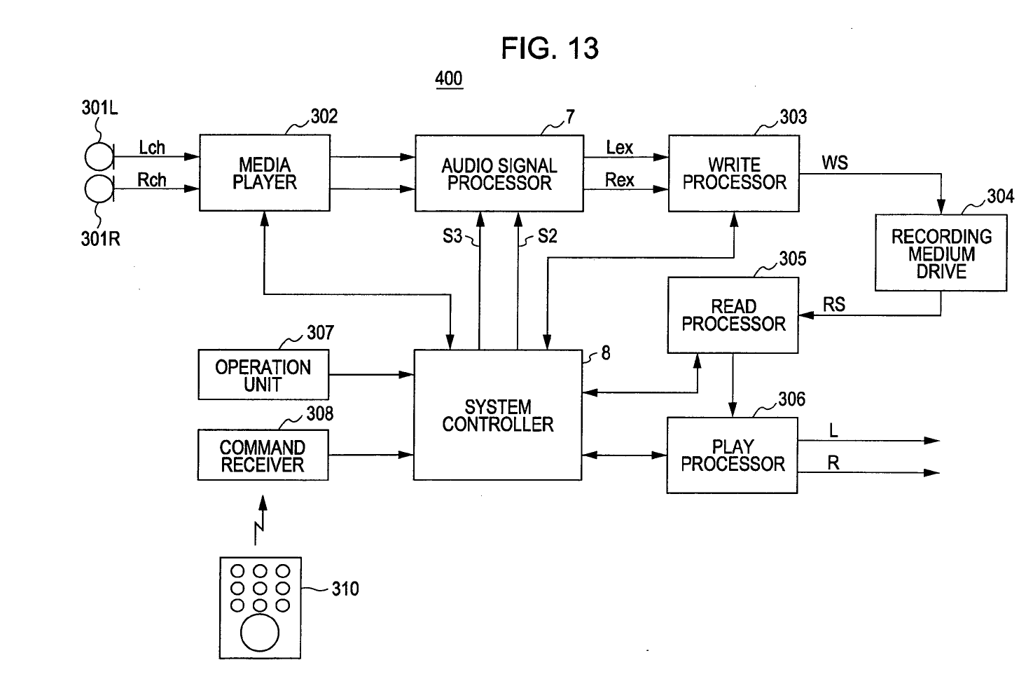

FIG. 13 is a block diagram illustrating the recording and reproducing apparatus 400 of the fourth embodiment. As shown in FIG. 13, elements identical to those of the reproducing apparatus 200 of the second embodiment of FIG. 9 are designated with the same reference numerals, and the detail discussion thereof is omitted herein. Also, as shown in FIG. 13, elements identical to those of the recording and reproducing apparatus 300 of the third embodiment of FIG. 12 are designated with the same reference numerals and the detailed discussion thereof is omitted herein.

More specifically, the recording and reproducing apparatus 400 of the fourth embodiment of FIG. 13 employs the audio signal processor 7 and the system controller 8 in the reproducing apparatus 200 of the second embodiment respectively using the audio signal processor 2 and the system controller 4 in the recording and reproducing apparatus 300 of FIG. 12.

Audio signals picked up by left and right microphones 301L and 301R are recorded on a recording medium of the recording medium drive 304. The system controller 8 generates the audio volume balance command signal S2 and the sound source type command signal S3 in response to the sound source type command and the audio volume balance command received from the user via the remote commander 310 and the command receiver 308. The system controller 8 then supplies the audio volume balance command signal S2 and the sound source type command signal S3 to the audio signal processor 7.

In response to the sound source type command signal S3 from the system controller 8, the audio signal processor 7 separates the Lch audio signal and the Rch audio signal, picked up by the left and right microphones 301L and 301R, and supplied via the amplifier 302, into an audio signal of a designated sound source and an audio signal of the other sound source, and then measures the audio volume balance.

The system controller 8 identifies the gain value Gi to the audio signal of the designated sound source and the gain value Go to the audio signal of the other sound source, in response to the measurement result of the audio volume balance between the audio signal of the designated sound source and the audio signal of the other sound source, and the audio volume balance command signal S2 from the system controller 8. Using the resulting gain values Gi and Go, the system controller 8 gain adjusts the audio signal of the designated sound source and the audio signal of the other sound source. The system controller 8 thus adjusts the audio volume balance between the audio signal of the designated sound source and the audio signal of the other sound source to the user's preference.

The audio signal of the designated sound source and audio signal of the other sound source, each having undergone the audio volume balance adjustment, are recorded on the recording medium of the recording medium drive 304 via the write processor 303.

To reproduce the audio signal recorded on the recording medium of the recording medium drive 304, the audio signal is read and reproduced in the same manner as described with reference to FIG. 12 in connection with the recording and reproducing apparatus 300 of the third embodiment. The audio signal recorded on the recording medium of the recording medium drive 304 is the one that has been audio volume balance adjusted by the audio signal processor 2 in response to the audio volume balance command signal S2 and the sound source type command signal S3 from the system controller 8. More specifically, the audio signal recorded on the recording medium of the recording medium drive 304 has been adjusted to satisfy the user's preference in the audio volume balance between the audio signal of the designated sound source and the audio signal of the other sound source. During playing, the audio signal is simply reproduced, and the user can enjoy listening to the audio signal at the audio volume balance satisfying the user's preference. In other words, the user is freed from the audio volume balance adjustment during playing.

The recording and reproducing apparatuses of the third and fourth embodiments is applicable to each of a recording and reproducing apparatus for MD (Mini Disc (Registered Trademark)), an audio recording and reproducing apparatus for an IC recorder or a cassette tape recorder, and an audio system in an audio and video recording apparatus such as a video camera. The recording and reproducing apparatuses of the third and fourth embodiments are applicable to an information processing apparatus such as a personal computer having an audio signal processing function.

Each of the apparatuses of the first through fourth embodiments of the present invention receives the separation angle command input and audio volume balance command input, or the sound source type command input and audio volume balance command input. A first user interface for receiving the separation angle command input and audio volume balance command input is described below.

In accordance with the first user interface, an audio volume value at each location angle of at least two channel audio signals in each frequency band, each channel being a mixture of a plurality of sounds, is expressed by color brightness in a two-dimensional plane with one axis representing frequency and the other axis representing location angle. Referring to the audio volume value thus represented, a target separation angle (location angle) command and audio volume balance command are input. In the following example, the first user interface is applied to the reproducing apparatus 100 of FIG. 1 of the first embodiment.

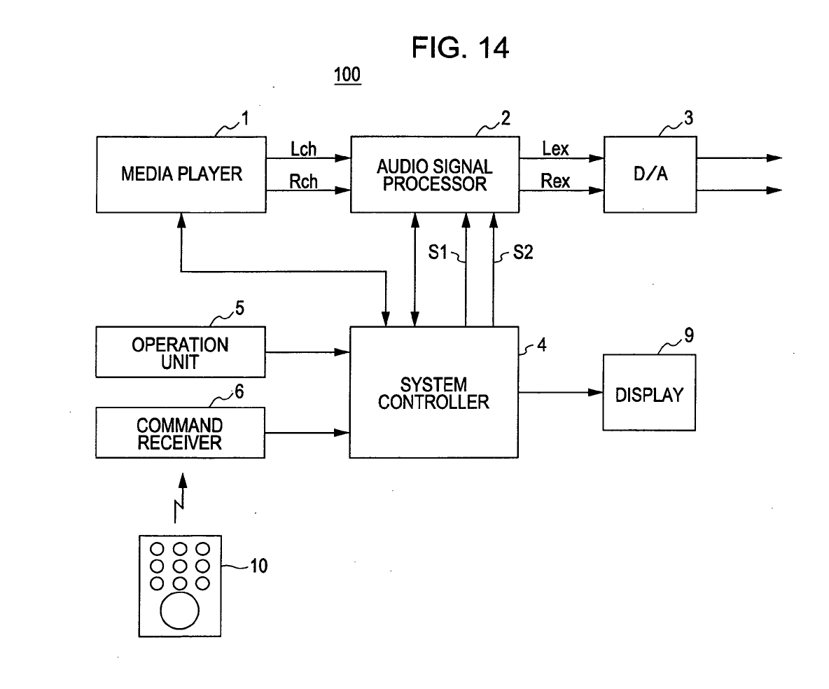

FIG. 14 is a block diagram illustrating the reproducing apparatus 100 incorporating the first user interface. In the reproducing apparatus 100 of FIG. 14, a display 9 is connected to the system controller 4 in the reproducing apparatus 100.

The audio signal processor 2 measures the audio volume value of the Lch audio signal and the Rch audio signal from the media player 1 at each location angle in a predetermined frequency band, and supplies the measurement results to the system controller 4. The audio signal processor 2 also supplies the Lch audio signal and the Rch audio signal to the digital-to-analog converter 3 as an audio signal Lex and an audio signal Rex for playing.

A variety of methods for measuring the audio volume value of the two channel audio signals at each location angle in each frequency band are known. For example, the technique disclosed in Japanese Patent Application No. 2005-327237 (Serial No. 0590529003) may be employed.

In accordance with Japanese Patent Application No. 2005-327237, the audio signal is segmented by every predetermined frequency band in a frequency band segmentation process (for example, into 4096 frequency bands in steps of 10.77 Hz in the case of sampling frequency of 44.1 kHz). The location angle of the audio signal segmented into each frequency band is measured. Only an audio signal of a sound source localized at a certain angle is thus extracted, or deleted, or adjusted in the audio volume value thereof. In this way, the audio volume value at each location angle is measured in each frequency band.

In response to the measurement results of the audio volume value on each location angle in each frequency band supplied from the audio signal processor 2, the system controller 4 generates information regarding each sound source contained in the audio signal to be reproduced, and supplies the generated information to the display 9 to be displayed thereon.

The display 9 includes a liquid-crystal display (LCD), an organic electroluminescence (EL) panel, a plasma display panel (PDP), or a cathode ray tube (CRT) and the control circuit thereof. Upon receiving the display data from the system controller 4, the display 9 displays on a display screen of the display element thereof an image responsive to the display data.

The reproducing apparatus 100 receives, via the remote commander 10 and the command receiver 6, a play command to reproduce the audio signal recorded on the recording medium loaded on the media player 1. The system controller 4 controls the media player 1, thereby reading the target audio signal from the recording medium and reproducing the audio signal via the audio signal processor 2 and the digital-to-analog converter 3.

In response to the measurement results of audio volume value at each location angle in each frequency band from the audio signal processor 2, the system controller 4 generates the data for displaying the information relating to the sound contained in the audio signal to be reproduced, and supplies the generated data to the display 9. In this way, the information relating to the source sound contained in the audio signal to be reproduced is thus displayed on the display screen of the display 9.

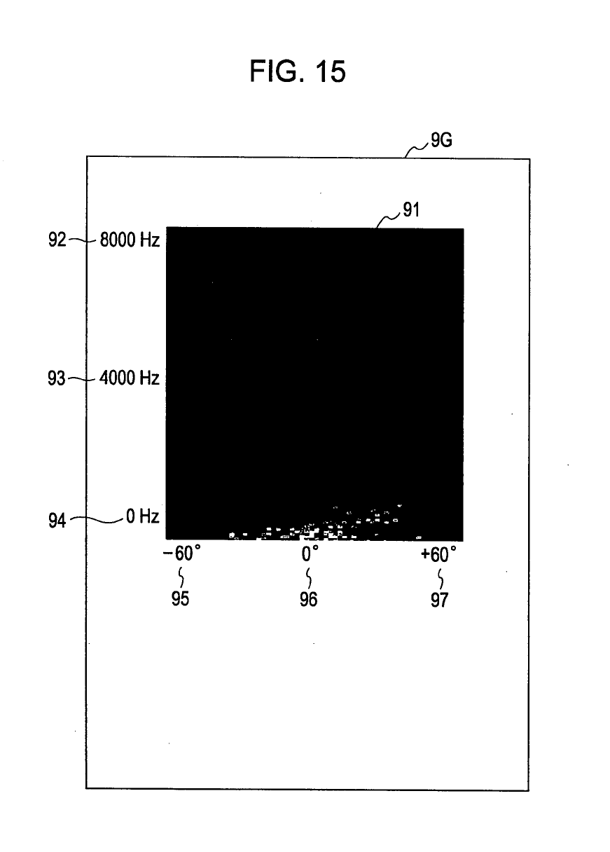

FIG. 15 illustrates a display example of the information relating to the source sound contained in the audio signal to be reproduced, displayed on the display screen of the display 9. More specifically, the audio volume value of the source sound present at each location angle in each predetermined frequency is represented by color brightness. As shown in FIG. 15, the outline represents a display screen 9G of the display 9. The display screen 9G includes an audio volume display area 91 that displays information relating to the source sound contained in the audio signal to be reproduced.

The horizontal axis represents the location angle of each source sound and the vertical axis represents frequency in the audio volume display area 91 in the display screen 9G of the display 9. The horizontal axis, representing 0° at the center point thereof and extending to the right end at 60° and to the left end at 60°, covers a total of 120°. The vertical axis extends from 0 Hz to 8000 Hz.

As shown in FIG. 15, black areas represent a low volume level and white areas represent a high volume level in the audio volume display area 91. The horizontal axis represents location angle in the audio volume display area 91. The audio volume values of the audio signals of sound sources localized on the left are plotted in the left portion of the horizontal axis, the audio volume values of the audio signals of sound sources localized on the right are plotted in the right portion, and the audio volume values of the audio signals of sound sources localized in the center are plotted in the center portion. The vertical axis represents frequency in the audio volume display area 91. The audio volume values in a high frequency band are plotted in the upper portion of the vertical axis, the audio volume values in a low frequency band are plotted in the lower portion, and the audio volume values in an intermediate frequency band are plotted in the middle portion.

An audio volume value plotted in a lower right portion of the audio volume display area 91 represents an audio volume value localized on the right and falling in the lower frequency band. Three components of location angle, frequency, and audio volume value are thus represented by the horizontal axis, the vertical axis, and the color brightness. As shown in FIG. 15, labels 92, 93 and 94 represent corresponding frequencies, and labels 95, 96 and 97 represent corresponding location angles.

As shown in FIG. 15, sound sources providing a large audio volume value are present within an angle range from −600 to +600 with respect to 0° and below a frequency of 4000 Hz, more specifically, within an angle rage from −30° to +30° and below a frequency of 2000 Hz.

In response to an operation input from the user, the system controller 4 in the reproducing apparatus 100 generates the separation angle command signal (location angle range command signal) S1 and the audio volume balance command signal S2, and then supplies the command signals S1 and S2 to the audio signal processor 2.

The system controller 4 can receive the operation input from the user via the operation unit 5 or the remote commander 10 and the command receiver 6. In the discussion that follows, the operation input from the user is received via the remote commander 10 and the command receiver 6. As previously discussed with reference to FIG. 2, the remote commander 10 includes the controls receiving the operation input from the user.

The user operates the controls on the remote commander 10 for direction commands to enter the separation angle (separation range angle) and the audio volume balance while monitoring the information relating to the sound source displayed on the display screen 9G of the display 9.

Upon receiving the commands, the system controller 4 generates the separation angle command signal S1 and the audio volume balance command signal S2, and supplies the command signals S1 and S2 to the audio signal processor 2. The audio signal processor 2 multiplies the audio signal of the sound source within the designated separation angle by a gain value determined taking into consideration the audio volume balance command signal S2 and also multiplies the audio signal of the sound source outside the designated separation angle by a gain value determined taking into consideration the audio volume balance command signal S2. The audio signal gain adjusted in response to the user command is thus reproduced.

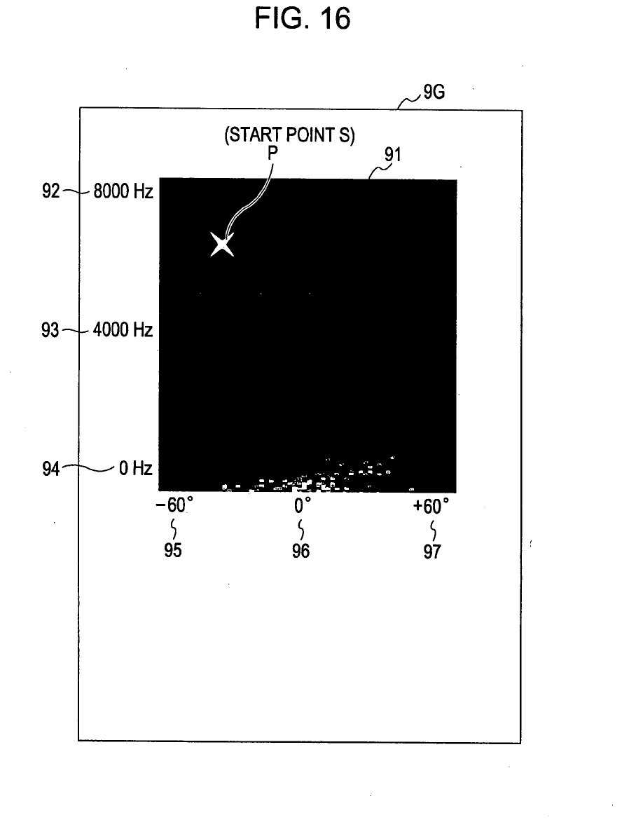

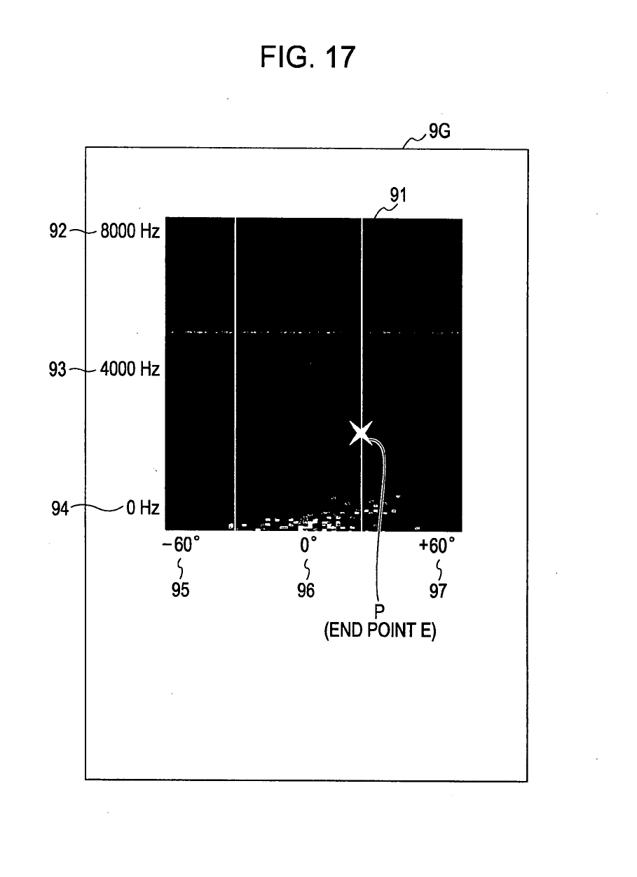

The procedure for setting the separation angle varying the audio volume balance and the procedure for modifying the audio volume balance between the audio signal within the specified angle and the audio signal outside the specified angle are described below with reference to the operation to the remote commander 10 and the display screen 9G of the display 9 changing in response to the operation to the remote commander 10. The display example of a display image with the separation angle designated as shown in of FIGS. 16 and 17 is described in detail below.

At a first phase of the operation, the playing process of the audio signal starts, and the display image is displayed on the display screen 9G of the display 9 as shown in FIG. 15. By performing a predetermined operation, a pointer P for indicating one of a start point and an end point is displayed as shown in FIG. 16. By operating the right key 10a and the left key 10b, the user places the pointer P at a position that is expected to become a start point S within a range of a selected separation angle (hereinafter referred to as a separation angle range). The user thus fixes the start point S. The separation angle range is a range defined by the location angle range of an sound image in the horizontal direction in the audio volume display area 91 of FIG. 15.

The user sets the start point S within the location angle range by operating the entry key 10e after shifting rightward the start point S of the location angle range by operating the right key 10a and after shifting leftward the start point S of the location angle range by operating the left key 10b. By displaying the pointer P indicating the current position superimposed on the display portion of the audio volume display area 91, the displaying of the start point S is facilitated.

In a second phase after determining the start point S, the right key 10a and the left key 10b are operated to shift the pointer P to an end point E of the selected separation angle range (location angle range) as shown in FIG. 17. The entry key 10e is then selected to enter the determined end point E.

More specifically, the user enters the end point E of the location angle range by operating the entry key 10e after shifting rightward the end point E of the location angle range by operating the right key 10a and after shifting leftward the end point E of the location angle range by operating the left key 10b.

The system controller 4 generates display data in response to the command input from the user and supplies the generated display data to the display 9. As shown in FIG. 17, a vertical line containing the selected start point S and a vertical line containing the end point E are displayed on the audio volume display area 91. The user can visibly recognize the indicated separation angle range (location angle range). The system controller 4 controls the audio signal processor 2, thereby outputting only the audio signal of the sound source within the designated range. The user can hear the indicated location angle range. In this way, the user can easily enter the end point E.

In a third phase in succession to the second phase of setting the start point S and the end point E of the separation angle range (location angle range), the audio volume balance between the audio signal within the location angle range defined by the start point S and the end point E and the audio signal outside the location angle range is varied by operating the up key 10c and the down key 10d on the remote commander 10.

More specifically, if the audio volume balance between the audio signal within the location angle range defined by the start point S and the end point E and the audio signal outside the location angle range is 1:1, the audio volume balance can be set to be 1.1:0.9 by operating the up key 10c. If the audio volume balance between the audio signal within the location angle range defined by the start point S and the end point E and the audio signal outside the location angle range is 1:1, the audio volume balance can be set to be 0.9:1.1 by operating the down key 10d.

From the first phase through the third phase, the user of the reproducing apparatus 100 selects a particular separation angle (location angle range), and adjusts the audio volume balance between the audio signal within the location angle range and the audio signal outside the location angle range. More specifically, the user selects a particular location angle range, and adjusts the audio volume balance between the two ranges by adjusting the audio volumes of the inner range and/or the outer range.

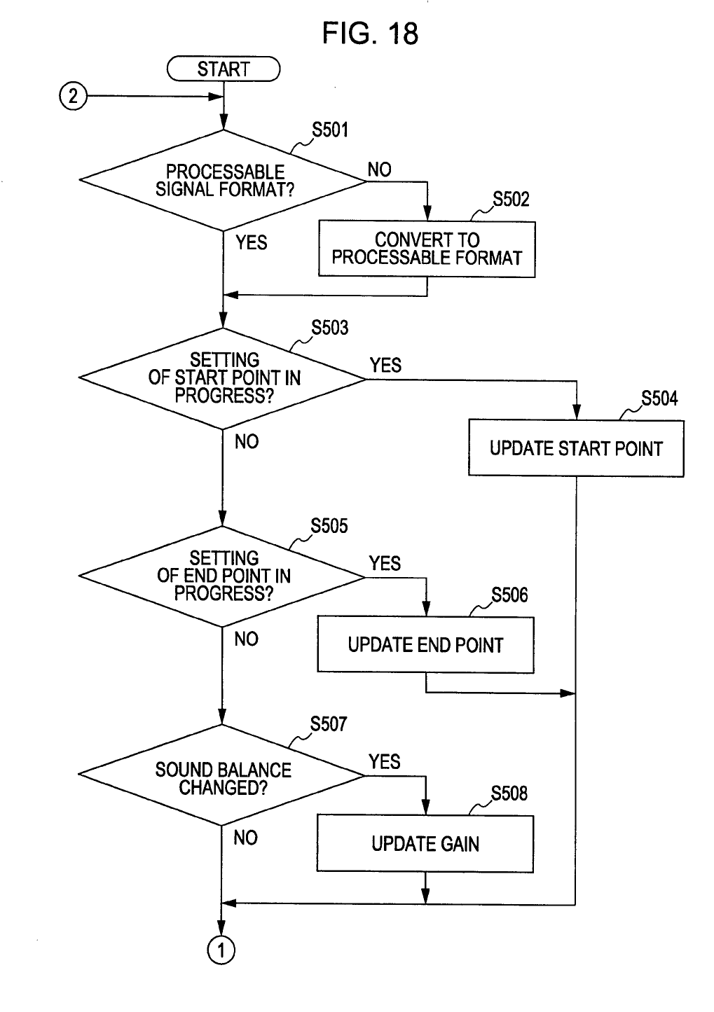

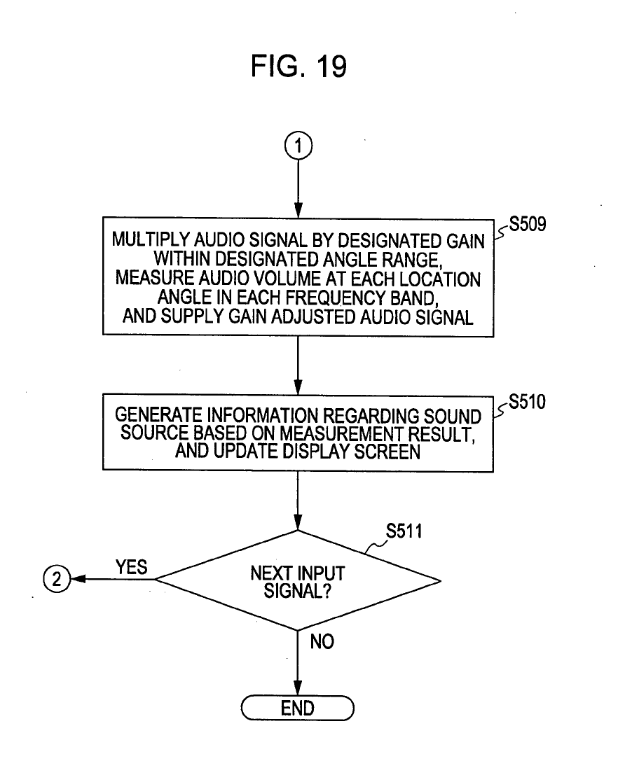

The above process may be implemented using software. FIGS. 18 and 19 are flowcharts of the separation angle command input and the audio volume balance command input process performed by the reproducing apparatus 100. The flowcharts are also applicable if the present invention is implemented using software.

The process of FIGS. 18 and 19 is a process that the audio signal processor 2, the system controller 4 and the display 9 perform in cooperation when the audio signal recorded on the recording medium loaded on the media player 1 is reproduced in response to a play command to reproduce the audio signal received via the remote commander 10 and the command receiver 6.

The system controller 4 in the reproducing apparatus 100 controls the audio signal processor 2, thereby determining whether the audio signal to be reproduced is in a processable format supported by own apparatus (step S501).

If it is determined in step S501 that the audio signal is not in a processable format supported by own apparatus, the system controller 4 controls the audio signal processor 2, thereby converting the audio signal into an audio signal in a processable format (step S502).

Subsequent to step S502 or if it is determined in step S501 that the audio signal is in a processable format supported by own apparatus, the system controller 4 determines through the remote commander 10 and the command receiver 6 whether the reception of the start point S of the adjustment range of the audio volume balance from the user is in progress, i.e., whether the setting of the start point S is in progress (step S503).

If it is determined in step S503 that the setting of the start point S is in progress, the system controller 4 updates the position (information) of the internally stored start point S in response to the command signal received from the remote commander 10 via the command receiver 6. The system controller 4 generates data to be used to modify a display position of the pointer P, and supplies the generated data to the display 9. The display position of the pointer P is thus updated (step S504). The system controller 4 then proceeds to step S509 of FIG. 19.

When a command signal indicating the operation of the entry key 10e is received from the remote commander 10 in step S504, the position of the pointer P is set as the position of the start point S. The system controller 4 may now be ready to receive the setting of the end point E. The setting operation of the start point S may be repeated until a command signal indicating the operation of the entry key 10e is received from the remote commander 10.

If it is determined in step S503 that the setting operation is not in progress, the system controller 4 determines through the remote commander 10 and the command receiver 6 whether the reception of the setting operation of the end point E of the adjustment range of the audio volume balance from the user is in progress, i.e., whether the setting operation of the end point E is in progress (step S505).

If it is determined in step S505 that the setting of the end point E is in progress, the system controller 4 updates the position of the end point E in response to a command signal received from the remote commander 10 via the command receiver 6, and generates data for updating the display position of the pointer P accordingly. The system controller 4 modify the display position of the pointer P by supplying the generated data to the display 9 (step S506). The system controller 4 then proceeds to step S509 of FIG. 19.

When a command signal indicating the operation of the entry key 10e is received from the remote commander 10 in step S506, the position of the pointer P at that time is set as the end point E. The system controller 4 may be ready to receive a modification operation of the audio volume balance. The setting operation of the end point E may be repeated after the setting of the start point S until the command signal indicating the pressing operation of the entry key 10e is received from the remote commander 10.

If it is determined in step S505 that the setting of the end point E is not in progress, the system controller 4 determines through the remote commander 10 and the command receiver 6 whether an adjustment operation to the audio volume balance has been received from the user, i.e., whether the audio volume balance has changed (step S507).

If it is determined in step S507 that the audio volume balance has changed, the system controller 4 updates the audio volume balance value internally stored with reference to the audio signals within and outside the designated range, in response to the command signal received from the remote commander 10 via the command receiver 6 (step S508). The system controller 4 proceeds to step S509 of FIG. 19.

When the command signal indicating the pressing operation of the entry key 10e is received from the remote commander 10 in step S508, the modified audio volume balance is set as a determined value. The setting operation of the audio volume balance is repeated after the setting of the end point E until the command signal indicating the pressing operation of the entry key 10e has been received from the remote commander 10.

If it is determined in step S507 that the audio volume balance has not changed, or subsequent to one of steps S504, S506 and S508, the system controller 4 proceeds to step S509 of FIG. 19.

The system controller 4 controls the audio signal processor 2, thereby multiplying the audio signal of the sound source within the separation angle range (location angle range) designated in the user operation by the gain value determined taking into consideration the audio volume balance value set in response to the user operation. The system controller 4 also controls the audio signal processor 2, thereby multiplying the audio signal of the sound source outside the separation angle range (location angle range) designated in the user operation by the gain value determined taking into consideration the audio volume balance value set in response to the user operation. The audio signal processor 2 thus measures the audio volume in each location angle in each frequency band, and supplies the gain-adjusted audio signal to the digital-to-analog converter 3 for playing (step S509).

In response to the measurement results of the audio volume of the audio signal at each location angle in each frequency band, the system controller 4 generates the data for displaying the information of each source sound contained in the audio signal to be reproduced, and supplies the generated data to the display 9. The system controller 4 thus updates the information regarding each source sound contained in the audio signal to be reproduced displayed on the display screen of the display 9 (step S510).

The system controller 4 determines whether a next audio signal to be input to the audio signal processor 2 is present (step S511). An affirmative answer to the determination in step S511 means that an audio signal to be processed is present. The system controller 4 return to steps S501 to repeat step S501 and subsequent steps. A non-affirmative answer in the determination in step S511 means that no audio signal to be processed is present. The system controller 4 ends the process of FIGS. 18 and 19.

The reproducing apparatus 100 expresses the audio volume of audio signals of at least two channels at each location angle in each frequency band using the color brightness in the two-dimensional plane with frequency and location angle plotted in the two axes. In the two-dimensional plane, the user selects a particular range, and adjusts the audio volume balance between the audio signal within the selected range and the audio signal outside the selected range.

The user selects a particular separation angle range (location angle range), and adjusts the audio volume balance between the audio signal within the selected range and the audio signal outside the selected range. If the audio signal to be reproduced is a music audio signal, the manner of enjoying content is expanded, for example, by making a musical instrument of interest or a singing voice more pronounced, or by making playing of a musical instrument quieter.

### Modifications

In the reproducing apparatus 100 of FIG. 14, the separation angle range (location angle range) is set using the remote commander 10. The present invention is not limited to this arrangement. The setting of the separation angle range can be easily performed by imparting a touchpanel function to the display screen 9G of the display 9.

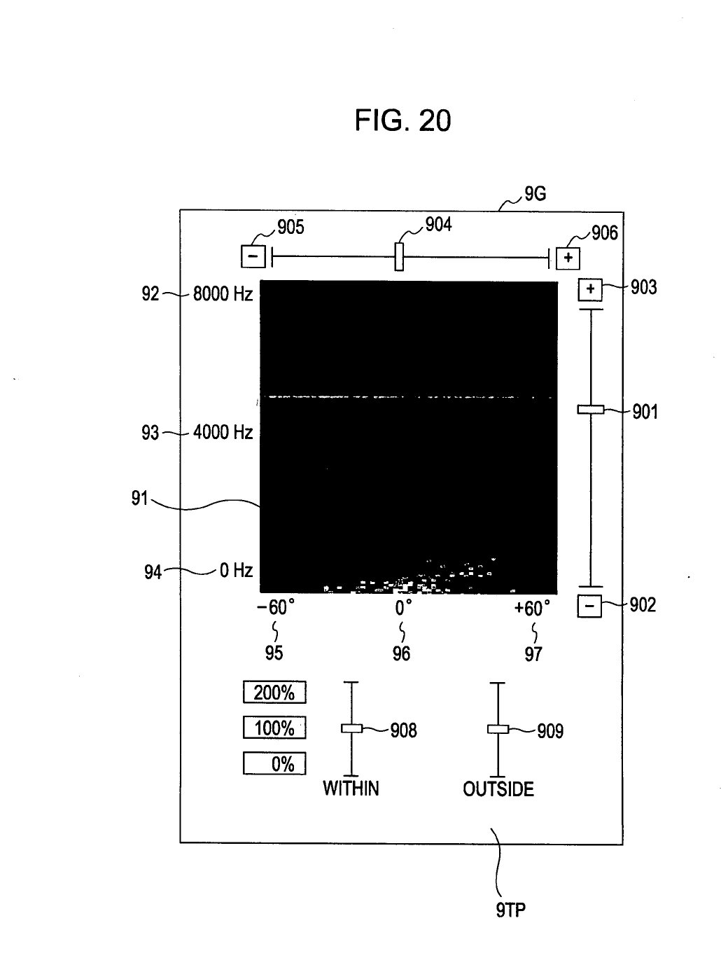

FIG. 20 illustrates a display example displayed on the display screen 9G of the display 9 having a touchpanel 9TP. The touchpanel 9TP is glued on the display screen 9G of the display 9. An image displayed on the display screen 9G and the touchpanel 9TP function as a receiving unit for receiving a user operation input.

The system controller 4 knows what display image is displayed at what position of the display screen 9G. When a touchpen or a finger touches the touchpanel 9TP, the touchpanel 9TP supplies coordinate data indicating a point of touch in the form of an electrical signal to the system controller 4. If a drag operation is performed, the touchpanel 9TP supplies to the system controller 4 coordinate data indicating a moving touch point in the form of an electrical signal.

The system controller 4 determines a process to be performed based on the coordinate data from the touchpanel 9TP and image information displayed on the display screen 9G in response to the coordinate data, and then performs the determined process. The location angle range may be determined and the audio volume balance may be modified by operating the touchpanel 9TP. Such a modification to the above embodiments is described below.

In such a modification, the display screen 9G of the display 9 includes the audio volume display area 91 serving as a display area for the information relating to each source sound contained in the audio signal to be reproduced. As shown in FIG. 20, labels 92, 93 and 94 represents corresponding frequencies, and labels 95, 96 and 97 represent corresponding location angles.

As in the audio volume display area 91 of FIGS. 15-17, the horizontal axis represents location angle of a sound image of each sound source, the vertical axis represents frequency, and the color brightness represents the level of audio volume of each sound source. The three components of location angle, frequency and audio volume level are plotted using the horizontal axis, the vertical axis, and the color brightness.

The separation angle range (location angle range) is designated by causing one of a touchpen or a finger to touch and slide on the display screen 9G. More specifically, the user touches the touchpen or finger at one point on the touchpanel 9TP glued on the display 9, moves the touchpen or finger in a touch state to another point on the touchpanel 9TP, and releases the touchpen or finger there.

By performing such a drag and drop operation, the system controller 4 sets as the start point S the first touch point and as the end point E the touch release point based on the coordinate data from the touchpanel 9TP and the corresponding display information. The system controller 4 thus sets the location angle range for modifying the audio volume balance defined by the start point S and the end point E.

As shown in FIG. 20, a slider 901, a button 902 and a button 903 are provided to modify a range of frequency to be displayed on the audio volume display area 91. If a portion of a slider range of the slider 901 above the current position thereof is touched, the slider 901 is shifted upward. Along with a position change of the slider 901, the frequency range displayed on the audio volume display area 91 is shifted upward.

As shown in FIG. 20, the frequency range is 0 Hz to 8000 Hz with the slider 901 centered. If the slider 901 is shifted upward by one quarter of the entire range, the system controller 4 shifts the frequency range of the audio volume display area 91 to a range from 2000 Hz to 10000 Hz.

If the user touches the touchpen or finger to the touchpanel 9TP on the button 902, the frequency range displayed on the audio volume display area 91 is narrowed. For example, as shown in FIG. 20, the frequency range to be displayed is now from 0 Hz to 8000 Hz. If the user touches the touchpen or finger to the touchpanel 9TP on the button 902, the system controller 4 narrows the frequency range of the audio volume display area 91 to 0 Hz to 4000 Hz.

If the user touches the touchpen or finger to the touchpanel 9TP on the button 903, the frequency range of the audio volume display area 91 is widened. For example, as shown in FIG. 20, the frequency range to be displayed is now from 0 Hz to 8000 Hz. If the user touches the touchpen or finger to the touchpanel 9TP on the button 903, the system controller 4 widens the frequency range of the audio volume display area 91 to 0 Hz to 16000 Hz.

Using the slider 901, the button 902 and the button 903, the user can change the frequency range displayed on the audio volume display area 91. When the frequency range is changed in response to the user operation, the frequencies indicated by the labels 92, 93 and 94 are changed accordingly.

A slider 904, a button 905 and a button 906 shown in FIG. 20 are used to modify the location angle range to be displayed on the audio volume display area 91. If a portion of a slider range of the slider 904 to the left of the current position thereof is touched, the slider 904 is shifted leftward, and the location angle range displayed on the audio volume display area 91 is shifted leftward in response to the position change of the slider 904.

As shown in FIG. 20, the location angle range is now from −60° to +60° with the slider 904 centered. If the slider 904 is shifted leftward by a quarter of the entire range, the system controller 4 shifts the location angle range of the audio volume display area 91 to a range from −90° to +30°.

If the user touches the touchpen or finger on the touchpanel 9TP on the button 905, the location angle range displayed on the audio volume display area 91 is narrowed. For example, as shown in FIG. 20, the location angle range is now from −60° to +60°. If the user touches the touchpen or finger on the touchpanel 9TP on the button 906, the system controller 4 narrows the location angle range of the audio volume display area 91 to −30° to +30°.

If the user touches the touchpen or finger on the touchpanel 9TP on the button 906, the location angle range to be displayed on the audio volume display area 91 is widened. For example, as shown in FIG. 20, the location angle range to be displayed is now from −60° to +60°. If the user touches the touchpen or finger on the touchpanel 9TP on the button 906, the system controller 4 widens the location angle range of the audio volume display area 91 to a range from −120° to +120°.

The user can thus modify the location angle range to be displayed on the audio volume display area 91 using the slider 904, the button 905 and the button 906. When the location angle range is modified, the location angles indicated by the labels 95, 96 and 97 are modified accordingly.

As shown in FIG. 20, a slider 908 is used to set a audio volume balance within the location angle range designated by the user. If a portion of a slider range of the slider 908 above the current position thereof is touched, the slider 908 is shifted upward, and the audio volume balance value within the designated range increases in response to the position change of the slider 908.

A slider 909 is used to set the audio volume balance outside the location angle range designated in the user operation. If the user touches a portion of a slider range of the slider 909 above the current position thereof, the slider 909 is shifted upward. The audio volume balance value outside the designated range increases in response to the position change of the slider 909.

As shown in FIG. 20, the audio volume balance values within and outside the designated location angle range and outside are now 1:1 with each of the slider 908 and the slider 909 centered at the slider ranges thereof. If the slider 908 is shifted upward by a quarter of the slider range, the system controller 4 changes the audio volume balance between the audio signal within the designated location angle range and the audio signal outside the designated location angle range to 1.5:1. If the slider 909 is shifted downward by a quarter of the slider range thereof, the system controller 4 changes the audio volume balance between the audio signal within the designated location angle range and the audio signal outside the designated location angle range to 1.5:0.5.

The system controller 4 controls the audio signal processor 2, thereby multiplying the audio signal of the sound source within the separation angle range (location angle range) designated in the user operation by the gain value determined taking into consideration the audio volume balance value set in response to the user operation. The system controller 4 also controls the audio signal processor 2, thereby multiplying the audio signal of the sound source outside the separation angle range (location angle range) designated in the user operation by the gain value determined taking into consideration the audio volume balance value set in response to the user operation. The audio signal processor 2 thus measures the audio volume in each location angle in each frequency band, and supplies the gain-adjusted audio signal to the digital-to-analog converter 3 for playing.

The reproducing apparatus 100 with the touchpanel arranged on the display screen can easily and quickly designate the separation angle and the audio volume balance without the need for frequently operating the controls on the remote commander 10.

In the first user interface for receiving the command input from the user discussed with reference to FIGS. 14-20, the separation angle (location angle) command and the audio volume balance command are received from the user, and the audio volume balance between the audio signal within the designated separation angle range and the audio signal outside the designated separation angle range is adjusted. The present invention is not limited to this method.

In addition to the separation angle range, the frequency range may also be designated. The audio volume balance may be adjusted between the audio signal within the designated range and the audio signal outside the designated range in terms of both designated separation angle range and the frequency range. A second user interface is described below. In the second user interface, the audio volume balance is adjusted between the audio signal within the designated range and the audio signal outside the designated range in terms of both designated separation angle range and the frequency range.

As the first user interface, the second user interface is applied to the reproducing apparatus 100 of FIG. 14. In the second user interface as in the first user interface, an audio volume value at each location angle of at least two channel audio signals in each frequency band, each channel being a mixture of a plurality of sounds, is expressed by color brightness in a two-dimensional plane with one axis representing frequency and the other axis representing location angle. Referring to the audio volume value thus represented, a target separation angle (location angle) command, a frequency range command, and an audio volume balance command are input.

In the discussion of the second user interface, FIGS. 14 and 15 used in the discussion of the first user interface are also referred to. The second user interface enabling the separation angle range and the frequency range to be designated is also applied to the reproducing apparatus 100 of FIG. 14.

In the second user interface, the audio signal processor 2 measures the audio volume value of the Lch audio signal and the Rch audio signal from the media player 1 at each location angle in each predetermined frequency band, and supplies the measurement results to the system controller 4. The audio signal processor 2 also supplies the Lch audio signal and the Rch audio signal to the digital-to-analog converter 3 as an audio signal Lex and an audio signal Rex for playing.

As previously discussed, the system controller 4 generates data for displaying on the display screen of the display 9 information relating to each source sound contained in the audio signal to be produced, based on the measurement results of the audio volume value at each location angle in each predetermined frequency band from the audio signal processor 2. The system controller 4 then supplies the generated information to the display 9.

When a command to reproduce the audio signal recorded on the recording medium loaded on the media player 1 is issued via the remote commander 10 and the command receiver 6, the system controller 4 controls the media player 1 to read the target audio signal from the recording medium and reproduces the target audio signal using the audio signal processor 2 and the digital-to-analog converter 3.

Based on the measurement results of the audio volume at each location angle in each predetermined frequency band from the audio signal processor 2, the system controller 4 generates the data for displaying the information relating to the source sound contained in the audio signal to be reproduced. The system controller 4 supplies the generated information to the display 9. The information relating to the source sound contained in the audio signal to be reproduced is thus displayed on the display screen 9G of the display 9.

The information relating to the source sound contained in the audio signal to be reproduced displayed on the display screen 9G of the display 9 is the audio volume value represented in the color brightness relating to the source sound present at each location angle in the predetermined frequency band as discussed with reference to FIG. 15. In the second user interface, the separation angle range, the frequency range, and the audio volume balance value are input to the system controller 4 via the operation unit 5 or the remote commander 10.

In the second user interface, the system controller 4 supplies the audio signal processor 2 with the separation angle command signal S1 containing the received separation angle range and the frequency range, and the audio volume balance command signal S2 containing the received audio volume balance value. In this way, the system controller 4 generates the separation angle command signal S1 containing the received separation angle range and the frequency range, and the audio volume balance command signal S2 containing the received audio volume balance value to supply the command signals S1 and S2 to the audio signal processor 2.

Upon receiving the separation angle command signal S1 containing the received separation angle range and the frequency range and the audio volume balance command signal S2 containing the received audio volume balance value, the audio signal processor 2 designates (sets) not only the separation angle range but also a target range of separation angle range and frequency range. The audio signal processor 2 can thus adjust the audio volume balance between the audio signal within the target range and the audio signal outside the target range. The structure of the audio signal processor 2 in the reproducing apparatus 100 incorporating the second user interface is different from the audio signal processor 2 in the reproducing apparatus 100 of the first embodiment illustrated in FIG. 3.

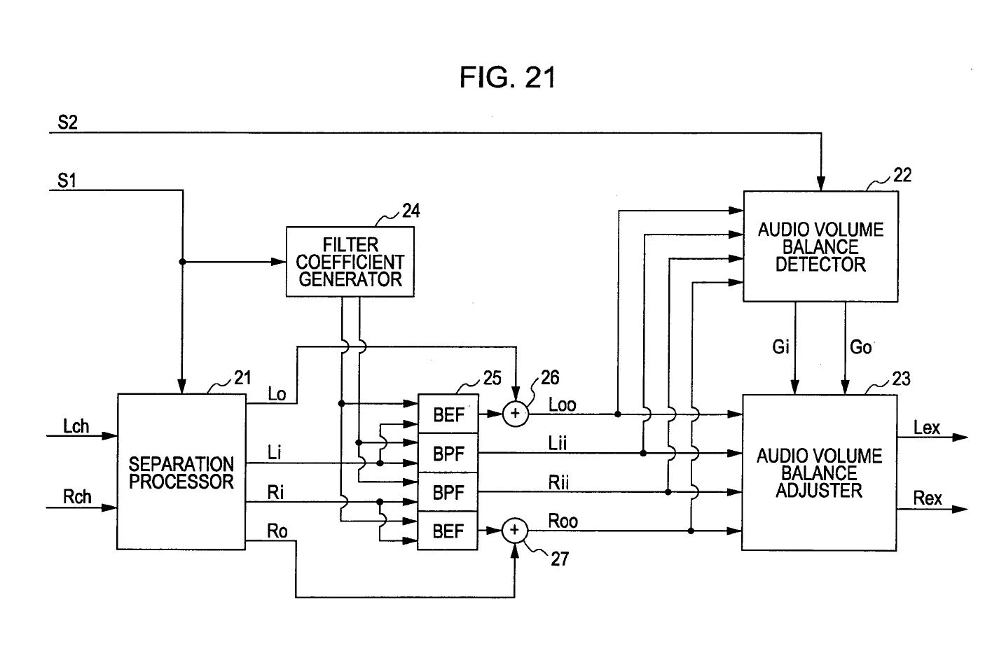

FIG. 21 is a block diagram illustrating the structure of the audio signal processor 2 in the reproducing apparatus 100 incorporating the second user interface. The audio signal processor 2 in the reproducing apparatus 100 incorporating the second user interface shown in FIG. 21, as opposed to FIG. 3, includes a filter coefficient generator 24, a filter unit 25, and adders 26 and 27 in addition to the separation processor 21, the audio volume balance detector 22, and the audio volume balance adjuster 23. The filter unit 25 is composed of two band elimination filters (BEFs) and two band-pass filters (BPFs).

As shown in FIG. 21, the system controller 4 supplies the separation angle command signal S1 containing the received separation angle range and the frequency range to each of the separation processor 21 and the filter coefficient generator 24. As previously discussed, in response to the separation angle range contained in the separation angle command signal S1, the separation processor 21 separates the audio signal of each of the left and right channels Lch and Rch into the audio signals Li and Ri of the sound source within the designated separation angle and the audio signals Lo and Ro of the sound source outside the designated separation angle, and supplies the audio signals Li and Ri of the sound source within the designated separation angle to BEF and BPF of Lch and BEF and BPF of Rch, respectively. The separation processor 21 also supplies the audio signals Lo and Ro of the sound source outside the designated separation angle to the adder 26 of Lch and the adder 27 of Rch, respectively.

In response to the frequency range contained in the separation angle command signal S1 supplied from the system controller 4, the filter coefficient generator 24 determines filter coefficients of the two BEFs and the two BPFs in the filter unit 25, and supplies the determined filter coefficients to respective filters.

The two BPFs in the filter unit 25 allow only a signal within the designated frequency range of the audio signals Li and Ri of the sound source within the designated separation angle to pass therethrough. To this end, the two BPFs in the filter unit 25 have the filter coefficients set therewithin to pass the signal within the designated frequency range therethrough.

The two BEFs in the filter unit 25 eliminate only a signal within the designated frequency range of the audio signals Li and Ri of the sound source within the designated separation angle, and passes only a signal outside the designated frequency range of the audio signals Li and Ri of the sound source within the designated separation angle to pass therethrough. The two BEFs in the filter unit 25 have the filter coefficients set therewithin to pass the signal outside the designated frequency to pass therethrough.

The two BPFs in the filter unit 25 output signals Lii and Rii within the designated frequency range of the signals within the separation angle (separation angle range). In other words, the two BPFs in the filter unit 25 output the audio signals Lii and Rii falling within an overlapping area of the designated separation angle range and the frequency range (audio signals within a designated target range defined by the separation angle range and the frequency range).

The BEFs in the filter unit 25 output audio signals outside the designated frequency range of the audio signals within the designated separation angle. The audio signals output from the two BEFs are respectively supplied to the adders 26 and 27. As shown in FIG. 21, the adders 26 and 27 receive the audio signals Lo and Ro of the sound source outside the designated separation angle. The adders 26 and 27 output audio signals Loo and Roo outside the designated frequency range of the audio signals outside the separation angle range.

In this way, the two BPFs in the filter unit 25 output the audio signals Lii and Rii within the designated frequency range of the signals of the left and right channels within the separation angle (separation angle range). The two BEFs in the filter unit 25 output the audio signals Loo and Roo outside the designated frequency range of the left and right channels. The audio signals Lii and Rii within the target range and the audio signals Loo and Roo outside the target range, of the left and right channels, are respectively supplied to each of the audio volume balance detector 22 and the audio volume balance adjuster 23.

The audio volume balance detector 22 measures the audio volume balance of the audio signals Lii and Rii within the target range and the audio signals Loo and Roo outside the target range, of the left and right channels in response to the audio volume balance value contained in the audio volume balance command signal S2 supplied from the system controller 4. In response to the audio volume balance value from the system controller 4, the audio volume balance detector 22 determines a gain value Gi to the audio signals Lii and Rii within the target range and a gain value Go to the audio signals Loo and Roo outside the target range, of the left and right channels so that the audio signals Lii and Rii within the target range and the audio signals Loo and Roo outside the target range reach an appropriate audio volume balance. The audio volume balance detector 22 supplies the gain values Gi and Go to the audio volume balance adjuster 23.

As shown in FIG. 21, the audio volume balance adjuster 23 performs the calculation operation defined by equation (1) based on the audio signals Lii and Rii within the target range and the audio signals Loo and Roo outside the target range, the gain value Gi to the audio signals Lii and Rii within the target range and the gain value Go to the audio signals Loo and Roo outside the target range. The audio volume balance adjuster 23 thus generates and outputs an output audio signal Lex of Lch and an output audio signal Rex of Rch. The audio volume balance adjuster 23 calculates equation (1) with Li=Lii, Ri=Rii, Lo=Loo and Ro=Roo. An equation other than equation (1) may also be used to generate the target audio signal.

The audio signal processor 2 in the reproducing apparatus 100 implementing the second user interface illustrated in FIG. 21 filters the audio signals Li and Ri within the designated separation angle range through the BPFs working at the designated frequency band, thereby generating the audio signals Lii and Rii within the target range, namely within the frequency range and with the separation angle range.

The audio signal processor 2 filters the audio signals Li and Ri within the designated separation angle range through the BEFs working at the designated frequency band, thereby generating the audio signals outside the frequency range. The audio signal processor 2 then adds the generated audio signals to the audio signals Lo and Ro outside the separation angle range, thereby generating the audio signal Loo and Roo outside the separation angle range and outside the designated frequency rage.

The filter coefficient generator 24 generates the filter coefficients of the BPFs and BEFs in the filter unit 25 in response to the designated frequency range in a static manner (with coefficients of all frequency range patterns stored) or in a dynamic manner (through calculation). Each of the BPFs and BEFs forming the filter unit 25 may be constructed of a finite impulse response (FIR) filter or an infinite impulse response (IIR) filter.

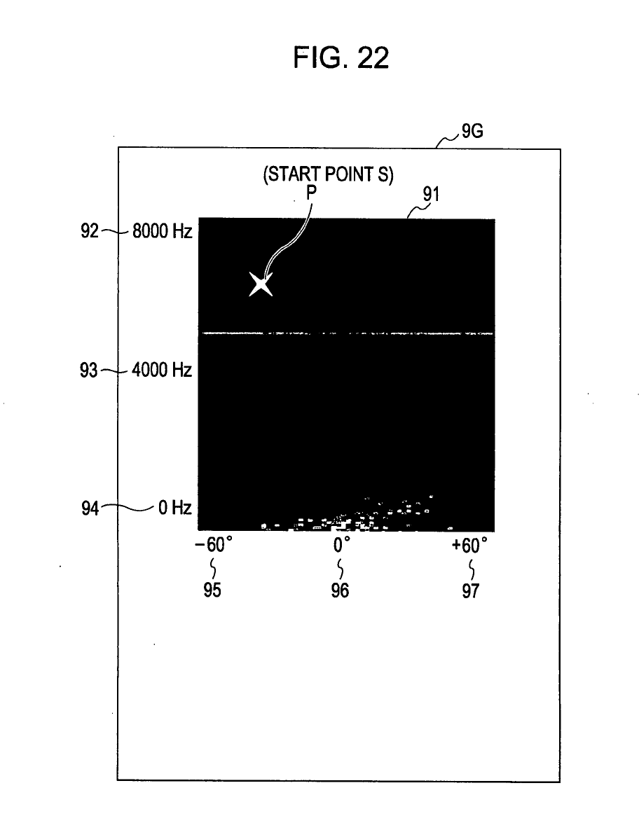

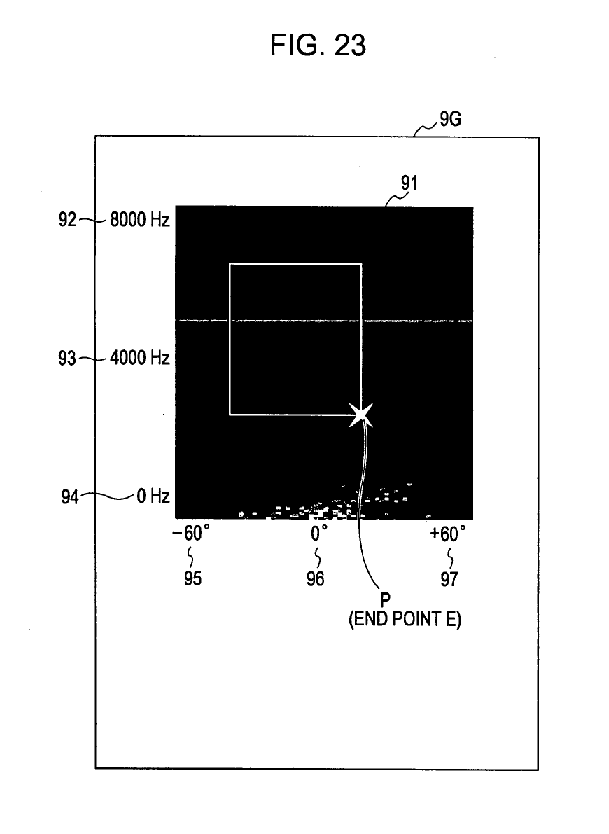

The procedure of setting the separation angle range and the frequency range for varying the audio volume balance and the procedure of modifying the audio volume balance between the audio signal within the target range defined by the separation angle range and frequency range and the audio signal outside the target range are described with reference to the operation performed on the remote commander 10 and the display image on the display screen 9G of the display 9 varying in response to the procedures. The display example of the display screen 9G is described when the separation angle range and frequency range are designated as shown in FIGS. 22 and 23.

In a first phase of the procedure, the playing operation starts to reproduce the audio signal. A display image is displayed on the display screen 9G of the display 9 in the second user interface in the same manner as in the first user interface discussed with reference to FIG. 15. By performing a predetermined operation, a pointer P for indicating one of a start point and an end point is displayed as shown in FIG. 22. By operating the right key 10a, the left key 10b, the up key 10c and the down key 10d, the user places the pointer P at a position that is expected to become a start point S. The start point S is entered by selecting the entry key 10e. The target range is a range defined by the separation angle range (location angle range of a sound image) and the frequency range.

The user sets the start point S by shifting rightward the start point S of the separation angle range with the right key 10a, by shifting leftward the start point S of the separation angle range with the left key 10b, by shifting up the start point S of the frequency range with the up key 10c, and by shifting down the start point S of the frequency range with the down key 10d. By selecting the entry key 10e, the user enters the start point S of the target range defined by the separation angle range and frequency range.

The command to shift the start point S is easily executed by displaying the pointer P indicating the current position on the display screen 9G of the audio volume display area 91.

In a second phase subsequent to the setting of the start point S, the user operates the right key 10a, the left key 10b, the up key 10c and the down key 10d to shift the pointer P to an end point E of the target range. With the pointer P placed at the end point E, the user selects the entry key 10e to enter.

The user sets the end point E by shifting rightward the end point E of the separation angle range with the right key 10a, by shifting leftward the end point E of the separation angle range with the left key 10b, by shifting up the end point E of the frequency range with the up key 10c, and by shifting down the end point E of the frequency range with the down key 10d. By selecting the entry key 10e, the user enters the end point E of the target range defined by the separation angle range and frequency range.

The system controller 4 generates display data in response to the input commands from the user, and supplies the generated display data to the display 9. As shown in FIG. 23, a rectangle having diagonal corner points placed at the start point S and the end point E is displayed on the audio volume display area 91. The designated target range (overlapping area of the separation angle range and frequency range) is thus visibly recognized.

The system controller 4 identifies, from the input start point S and end point E, the separation angle range (a range defined by the start point S and the end point E in a horizontal direction in FIG. 23) and the frequency range (a range defined by the start point S and the end point E in a vertical direction in FIG. 23). The system controller 4 thus generates the separation angle command signal S1 containing the separation angle range and frequency range, and supplies the separation angle command signal S1 to the audio signal processor 2.

In a second phase subsequent to the setting of the start point S and the end point E of the target range defined by the separation angle range and frequency range, the audio volume balance between a range defined by a rectangle having the diagonal corner points placed at the start point S and the end point E and the area outside the range is varied by operating the up key 10c and the down key 10d on the remote commander 10.

The system controller 4 receives the audio volume balance command via the up key 10c and the down key 10d on the remote commander 10. The system controller 4 generates the audio volume balance command signal S2 containing the audio volume balance value responsive to the received input command, and then supplies the audio volume balance command signal S2 to the audio signal processor 2. As discussed with reference to FIG. 21, the audio volume balance between the designated target range and the outside of the designated target range can thus adjusted.

If the audio volume balance value between the designated range defined by the current start point S and end point E and the outside of the designated range is 1:1, the operation of the up key 10c may modify the audio volume balance value to 1.1:0.9. If the audio volume balance value between the designated range defined by the current start point S and end point E and the outside of the designated range is 1:1, the operation of the down key 10d may modify the audio volume balance value to 0.9:1.1.

By performing the operation from the first phase to the third phase, the user of the reproducing apparatus 100 designates the target range defined by the overlapping area of the separation angle range and frequency range, and adjusts the audio volume balance between the designated range and the outside of the designated range. More specifically, the user selects a particular separation angle range and a particular frequency range, and adjusts the audio volume in the selected range and/or the outside of the selected range.

The process of the system controller 4 performed in the second user interface is also identical to the process in the first user interface discussed with reference to FIGS. 18 and 19. More specifically, the start point S and the end point E are designated to define the target range. By issuing the adjustment command to the audio volume balance between the target range and the outside of the target range, the audio volume balance is adjusted.

In the second user interface as in the first user interface as discussed with reference to FIG. 20, the target range as the overlapping area of the separation angle range and frequency range is designated by setting the start point S and the end point E on the touchpanel 9TP on the display screen 9G. The audio volume balance is designated. The audio volume balance between the target range and the outside of the target range is thus adjusted.

In the case of the second user interface, the audio signal processor 2 as configured in FIG. 21 adjusts the audio volume balance between the designated range defined by the separation angle range and frequency range and the outside of the designated range. The audio signal processor 2, configured as shown in FIGS. 5 and 6, also adjusts the audio volume balance between the designated range defined by the separation angle range and frequency range and the outside of the designated range.

In the first user interface, the separation angle range is designated. In the second user interface, the designated range defined by the separation angle range and frequency range is used. When the type of a target audio signal is designated as in one of the second and fourth embodiments, a variety of selection methods may be used. For example, the types of designated audio signals may be registered beforehand in the reproducing apparatus or the recording and reproducing apparatus and a target audio signal may be selected from the recorded types of designated audio signals.

The separation angle range is designated in the first user interface, and the designated range defined by the separation angle range and frequency range is designated in the second user interface. Alternatively, only the frequency range is designated, and the audio volume balance between the frequency range and the outside of the frequency range may be adjusted.

In accordance with the first and second embodiments, the media player 1 reproduces an audio signal (and a video signal) from the recording medium. The present invention is not limited to this arrangement. The present invention is applicable to a reproducing apparatus such as a tuner that receives and demodulates a variety of broadcast signals and outputs an audio signal (and a video signal). For example, the tuner receives an amplitude modulation (AM) broadcast signal, a frequency modulation (FM) broadcast signal, a television broadcast signal, and a satellite broadcast signal.

The present invention is applicable to an audio signal processing apparatus such as an amplifier rather than the media player 1 or the tuner. For example, the audio signal processing apparatus receives one of an audio signal reproduced (received) by an external device and performs an audio signal process on the input audio signal.

The present invention is applicable to a recording apparatus or a recording and reproducing apparatus. The recording apparatus or the recording reproducing apparatus may includes a tuner that receives and demodulates one of an amplitude modulation (AM) broadcast signal, a frequency modulation (FM) broadcast signal, a television broadcast signal, and a satellite broadcast signal and outputs an audio signal (and a video signal). The recording apparatus or the recording and reproducing apparatus stores the received and tuned broadcast signal onto a recording medium thereof.

In the audio volume display area 91 of the display screen 9G of the display 9 in FIGS. 15-17, 20, 22 and 23, the higher the level of audio volume, the more white the plot of audio signal becomes, and the lower the level of audio volume, the more black, the plot of audio signal becomes. Alternatively, the higher the level of audio volume, the more black the plot of audio signal becomes, and the lower the level of audio volume, the more white the plot of audio signal becomes.

The audio volume display area 91 on the display screen 9G of the display 9 may be color display. For example, the display color may be changed in steps of predetermined separation angle range. The higher the level of audio volume, the deeper the color of the plot of audio signal becomes, and the lower the level of audio volume, the lighter the color of the plot of audio signal becomes. Alternatively, the higher the level of audio volume, the lighter the color of the plot becomes, and the lower the level of audio volume, the deeper the color of the plot becomes. The display color may be changed on a per separation angle range basis and on a per frequency band basis, and within any predetermined separation range and predetermined frequency range, the color may be changed according to the rules described above.

The level of audio volume may be represented not only in color but also in a three-dimensional manner in the audio volume display area 91 on the display screen 9G of the display 9. The audio volume may be represented on a three-dimensional screen rather than on a two-dimensional screen. The vertical axis and the horizontal axis may be reversed. In other words, the vertical axis may represent location angle while the horizontal angle may represent frequency.

In the first user interface discussed with reference to FIGS. 14-20, the separation angle range is selected and the audio volume balance between the selected range and the outside of the selected range is adjusted by operating the right key 10a, the left key lob, the up key 10c and the down key 10d on the remote commander 10. Another procedure and another method may be used to designate the range. A pointing device such as a mouse or a touchpanel other than the remote commander may be used to designate a range.

In the case of the mouse, the user clicks on a mouse button to set the start point S, then drags the mouse to an end point E (moves a cursor of the mouse), and releases the mouse button there to enter the end point E.

In the modifications discussed with reference to FIGS. 14-20, a single separation angle range is set. A plurality of separation angle ranges may be set to modify the audio volume balance.

In the second user interface discussed with reference to FIGS. 21-23, the rectangle having the diagonal corner points at the start point S and the end point E is set for the separation angle range and frequency range. Alternatively, a circle or an ellipse may be used. The inside area of the circle or the ellipse may be a designated range.

The target area of the separation angle range and frequency range may be designated by the inside area of a circle centered on the start point S and having a radius passing the end point E. The target area of the separation angle range and frequency range may be designated by the inside area of a closed loop that the user draws using a mouse or a touchpanel. Any procedure, method, and device may be used as long as a range is designated therewith.

In the second user interface discussed with reference to FIGS. 21-23, a single target range defined by the separation angle range and frequency range is used. A plurality of target ranges may be used and the audio volume balance may be modified in each of the target ranges.

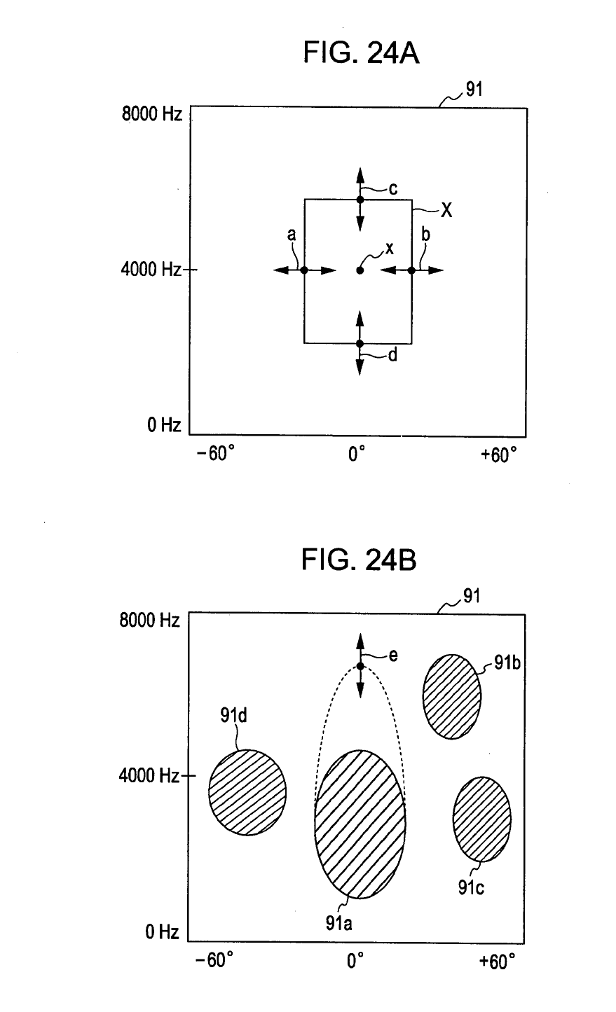

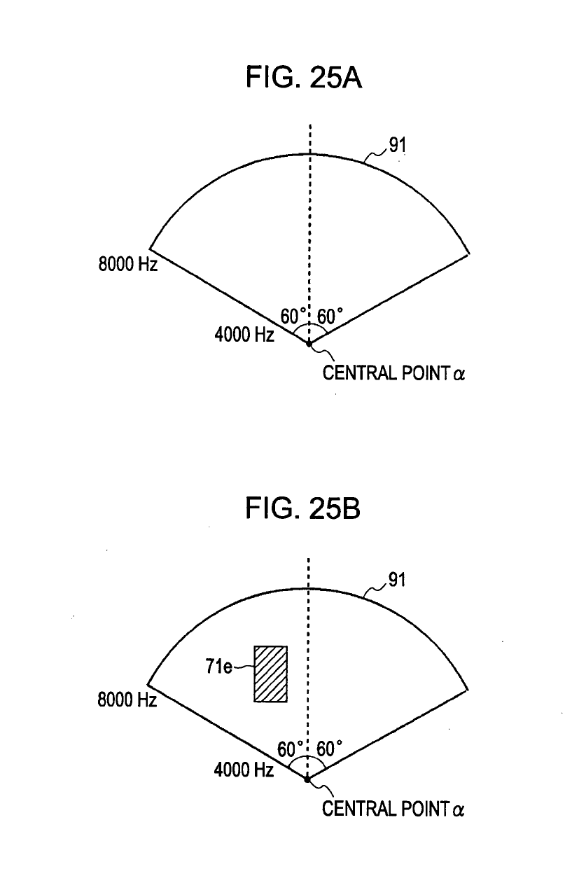

FIGS. 24A and 24B and FIGS. 25A and 25B illustrate other examples of target ranges (defined by the separation angle range and frequency range). As shown in FIG. 24A, the user may designate a single point x with a pointing device and the separation angle range and the frequency range are arranged centered on the point x.

As shown in FIG. 24A, the separation angle range contains an overall range of 20° centered on the point x, namely, a 10° range to the right and to the left to the point x, and the frequency range contains an overall range of 4000 Hz, namely, a 2000 Hz range above and a 2000 Hz below the point x. Thus, a rectangular area X automatically results. As represented by arrows a, b, c and d, the rectangle area X can be expanded or contracted by moving the four sides thereof.

As shown in FIG. 24B, an ellipse is designated as a first range by designating one point. In FIG. 24B as in FIG. 24A, a single point x is designated first. An ellipse having a vertically aligned major axis is set up to be centered on the point x. As shown by an arrow e in FIG. 24B, the ellipse may be expanded or contracted.

The ellipse is used to set the separation angle range and frequency range. The present invention is not limited this arrangement. Alternatively, a circle or a semi-circle or any of a variety of shapes may be used to set the range. By modifying the range, the user sets a target range.

As represented by ranges 91a, 91b, 91c and 91d in FIG. 24B, a plurality of separation angle ranges (each determining the separation angle range and frequency range) can be set up. The audio volume balance between each of the ranges 91a, 91b, 91c and 91d and the outside thereof is designated. The audio volume balance between each of the ranges 91a, 91b, 91c and 91d and the outside thereof is thus adjusted.

More specifically, the audio volume balance values of audio signals of musical instruments corresponding to the ranges 91a, 91b, 91c and 91d are increased and the audio volume balance values of other musical instruments or noise sound are decreased. Conversely, the audio volume balance values of audio signals of musical instruments corresponding to the ranges 91a, 91b, 91c and 91d may be decreased and the audio volume balance values of other musical instruments may be increased.

A range having a target source sound is set up in view of a spread of source sounds contained in audio content, and the audio volume balance is adjusted. In other words, the manner of balance adjustment is determined depending on an area (a separation angle range identified by a frequency range and/or a location angle range of a sound image) containing a sound source from which an audio signal is derived, and the audio volume balance adjustment is performed in accordance with the manner.

As shown in FIG. 25A, the audio volume display area 91 may have a sector shape. As shown in FIG. 25A, the center angle of the sector matches the location angle and each of the radial lines represents the frequency range. The position of the sound source contained in the audio signal is intuitively understood if the central point a of the sector represents a listener's position.

A range of a sound source in which a sound image is localized on the left of the listener is now designated. For example, as shown in FIG. 25B, a range 71e is set up on the left of the listener. By expanding or contracting the range 71e or shifting the range 71e in position, the frequency range and the location angle range containing the target sound source are set up. The shape of the audio volume display area 91 is not limited to the rectangle and the sector. A variety of shapes, such as a circle, an ellipse, a diamond, a trapezoid, may be used.

In each of the above-described embodiments, a musical instrument may be identified from frequency characteristics and overtone frequency components of musical instruments, and an image and a name of the musical instrument may be displayed on the audio volume display area 91 of the display 9. The type of a target sound source may be indicated.

The present invention is applicable to a reproducing apparatus, a recording apparatus, and a recording and reproducing apparatus, each apparatus for reproducing or recording an audio signal. The present invention is also applicable to an audio signal processing apparatus such as a receiver apparatus having a function for receiving and demodulating a broadcast signal, a personal computer having a function for reproducing music and video, or a power amplifier for performing an amplification process in response to an audio signal. The present invention is also applicable to a variety of electronic apparatuses for processing content signals composed an audio signal, and audio/visual (AV) signals containing an audio signal and a video signal to be reproduced in synchronization.

The designated separation angle and the audio volume balance or the type of sound source and the audio volume balance may be associated with an identification ID of content to be processed, and then stored on a memory in the system controller 4. When corresponding content is reproduced, the audio signals in the designated range and/or the outside of the designated range is gain adjusted in a designated manner to be reproduced to the user's preference.

The designated separation angle and the audio volume balance or the type of sound source and the audio volume balance may be imparted to content data such as the audio signal. If the content data is transferred to another apparatus, the content is reproduced on that apparatus based on the gain values of the designated range and/or the outside of the designated range and the designated frequency range and the location angle range.

The adjustment responsive to the designated separation angle and the audio volume balance or the adjustment responsive to the type of sound source and the audio volume balance may be applied to the content data in whole or in part.

In this case, the application time of the adjustment may be designated using time, the number of frames, and information specifying a position on the content. For example, the adjustment is applied to the entire content, or to the content for a period starting at some time after the head of the content, or for a period starting at several frames after the head of the content.

In response to the separation angle and the audio volume balance from the user, the apparatus of embodiments of the present invention determines audio volume balance between the audio signal of the sound source localized within the separation angle and the audio signal of the sound source localized outside the separation angle, and automatically adjusts the audio volume balance. The apparatus thus processes the content at an appropriate audio volume balance without the need for the user's intervention each time.

In response to the type of sound source and the audio volume balance from the user, the apparatus of embodiments of the present invention determines the audio volume balance between the audio signal of the designated sound source and the audio signal of the other sound source, and automatically adjusts the audio volume balance. The apparatus thus processes the content at an appropriate audio volume balance without the need for the user's intervention each time.

More specifically, the separation angle command information, the sound source type command information, and the audio volume balance information are input and stored on the memory of the apparatus or attached to the audio signal (audio content) as metadata. Based on these pieces of information, the voice of a target person or the sound of a target musical instrument is pronounced more while the rest of sound is made quieter. An audio signal, such as mechanical noise or the sound of wind, may present difficulty in hearing an audio signal of a target sound source. Such an interfering audio signal can be made less audible.

In response to the separation angle command and the audio volume balance command from the user, or the sound source type command and the audio volume balance command, the apparatus of embodiments of the present invention provides an appropriate audio volume balance without the need for the user's intervention for adjustment.

It should be understood by those skilled in the art that various modifications, combinations, sub-combinations and alterations may occur depending on design requirements and other factors insofar as they are within the scope of the appended claims or the equivalents thereof.

What is claimed is:

1. An apparatus for processing an audio signal, comprising:
a separator for separating an input audio signal into a first audio signal designated by a user and a second audio signal not containing the first audio signal;
a measurement unit for measuring an audio volume balance between the first audio signal and the second audio signal; and
an adjuster for calculating an adjustment value to an audio volume of the first audio signal and an adjustment value to an audio volume of the second audio signal based on a designated audio volume balance designated by the user, and adjusting the audio volume balance between the first and second audio signals.

2. The apparatus according to claim 1, wherein the separator separates, as the first audio signal, an audio signal localized within a separation angle designated by the user and, as the second audio signal, an audio signal of a sound source localized outside the separation angle.

3. The apparatus according to claim 1, wherein the separator separates, as the first audio signal, an audio signal of a sound source of a type designated by the user and, as the second audio signal, an audio signal of a sound source not containing the sound source type designated by the user.

4. The apparatus according to claim 1, further comprising a recorder for recording the first audio signal and the second audio signal with the audio volume balance adjusted by the adjuster.

5. The apparatus according to claim 1, further comprising a memory for storing a plurality of pieces of audio model data,
wherein the separator separates, as the first audio signal, an audio signal of a human voice and, as the second audio signal, an audio signal that is not human voice.

6. The apparatus according to claim 1, further comprising a memory for storing a plurality of pieces of musical instrument model data,
wherein the separator separates, as the first audio signal, an audio signal of a musical instrument sound and, as the second audio signal, an audio signal that contains no musical instrument sound.

7. A method for processing an audio signal, comprising steps of:
separating an input audio signal into a first audio signal designated by a user and a second audio signal not containing the first audio signal;
measuring an audio volume balance between the first audio signal and the second audio signal; and
calculating an adjustment value to an audio volume of the first audio signal and an adjustment value to an audio volume of the second audio signal based on a designated audio volume balance designated by the user, and adjusting the audio volume balance between the first and second audio signals.

8. The method according to claim 7, wherein the separating step comprises separating, as the first audio signal, an audio signal localized within a separation angle designated by the user and, as the second audio signal, an audio signal of a sound source localized outside the separation angle.

9. The method according to claim 7, wherein the separating step comprises separating, as the first audio signal, an audio signal of a sound source of a type designated by the user and, as the second audio signal, an audio signal of a sound source not containing the sound source type designated by the user.

10. The method according to claim 7, further comprising a step of recording the first audio signal and the second audio signal with the audio volume balance adjusted by the adjuster.

11. The method according to claim 7, further comprising a step of storing a plurality of pieces of audio model data,
wherein the separating step includes separating, as the first audio signal, an audio signal of a human voice and, as the second audio signal, an audio signal that is not human voice.

12. The method according to claim 7, further comprising a step of storing a plurality of pieces of musical instrument model data,
wherein the separating step includes separating, as the first audio signal, an audio signal of a musical instrument sound and, as the second audio signal, an audio signal that contains no musical instrument sound.

13. A program for causing a computer to process an audio signal, the program comprising:
separating an input audio signal into a first audio signal designated by a user and a second audio signal not containing the first audio signal;
measuring an audio volume balance between the first audio signal and the second audio signal; and
calculating an adjustment value to an audio volume of the first audio signal and an adjustment value to an audio volume of the second audio signal based on a designated audio volume balance designated by the user, and adjusting the audio volume balance between the first and second audio signals.

14. The program according to claim 13, wherein the act of separating comprises separating, as the first audio signal, an audio signal localized within a separation angle designated by the user and, as the second audio signal, an audio signal of a sound source localized outside the separation angle.

15. The program according to claim 13, wherein the act of separating comprises separating, as the first audio signal, an audio signal of a sound source of a type designated by the user and, as the second audio signal, an audio signal of a sound source not containing the sound source type designated by the user.

16. The program according to claim 13, further comprising recording the first audio signal and the second audio signal with the audio volume balance adjusted by the adjuster.

17. The program according to claim 13, further comprising storing a plurality of pieces of audio model data,
wherein the act of separating includes separating, as the first audio signal, an audio signal of a human voice and, as the second audio signal, an audio signal that is not human voice.

18. The program according to claim 13, further comprising storing a plurality of pieces of musical instrument model data,
wherein the act of separating includes separating, as the first audio signal, an audio signal of a musical instrument sound and, as the second audio signal, an audio signal that contains no musical instrument sound.
